(19) United States
(12) Patent Application Publication
(10) Pub. No.: US 2022/0275241 A1
(43) Pub. Date: Sep. 1, 2022

(54) PHOTOSENSITIVE RESIN COMPOSITION AND ORGANIC EL ELEMENT PARTITION WALL

(71) Applicant: SHOWA DENKO K.K., Tokyo (JP)

(72) Inventors: Kentaro FURUE, Tokyo (JP); Yoshikazu ARAI, Tokyo (JP)

(73) Assignee: SHOWA DENKO K.K., Tokyo (JP)

(21) Appl. No.: 17/637,622

(22) PCT Filed: Jun. 9, 2020
(86) PCT No.: PCT/JP2020/022733

§ 371 Date: Feb. 23, 2022

(30) Foreign Application Priority Data
Aug. 28, 2019 (JP) 2019-155417

(51) Int. Cl. C09D 163/04; C09D 133/14; C09D 7/41; C09D 7/63; H01L 51/52

(52) U.S. Cl. CPC C09D 163/04; C09D 133/14; C09D 7/41; C09D 7/63; H01L 51/5284

(57) ABSTRACT

The present invention reduces inhibition of light sensitization of a photosensitive resin composition containing a black dye and increases sensitivity by improving pattern forming ability. The photosensitive resin composition according to one embodiment of the present invention contains a binder resin (A), a radiation-sensitive compound (B), and a dye (C), wherein the dye (C) contains a black dye (C1) and a dye (C2) other than (C1), the dye (C2) has an absorption maximum at a wavelength of 480-550 nm in an wavelength range of 300-800 nm, and, when the absorbance of the dye (C2) at the absorption maximum wavelength is defined as Abs1 and the average absorbance of the dye (C2) at wavelengths 560-600 nm is defined as Abs2, Abs2/Abs1 equals 0.1-1.0.

### FIELD

The present invention relates to a photosensitive resin composition, and an organic EL element barrier rib, an organic EL element insulating film, and an organic EL element that use the same. More particularly, the present invention relates to a photosensitive resin composition containing a black dye, and an organic EL element barrier rib, an organic EL element insulating, film, and an organic EL element that use the same.

### BACKGROUND

In display devices, such as an organic EL display (OLED), barrier ribs are used in gaps of a coloring pattern in the display region or at the edge of the periphery of the display region, in order to improve display properties. In the manufacture of organic EL display devices, in order to ensure that pixels of an organic material do not touch each other, barrier ribs are first formed, then the pixels of an organic material are formed between the barrier ribs. Such barrier ribs are generally formed by photolithography using a photosensitive resin composition and have electrical insulating properties. More specifically, a photosensitive resin composition is applied onto a substrate using a coating device, and after volatile components are removed by heating, etc., the photosensitive resin composition is exposed to light through a mask. Next, unexposed parts, in the case of a negative tone, and exposed parts, in the case of a positive tone, are removed with a developer, such as an aqueous alkaline solution, thereby developing the same. The obtained pattern is heat treated and barrier ribs (insulating film) are formed. Next, films of an organic material that emit one of three colors, i.e., red, green or blue, are formed between the barrier ribs using an inkjet method, etc., and pixels of the organic EL display device are formed.

Recently in this field, there is a demand for more compact display devices, and due to the diversification of the content displayed, there is also a demand for higher pixel performance and higher resolution. For the purpose of increasing the contrast of a display device, thereby improving visibility, colorants have been used to impart light shielding properties to the barrier ribs. However, in cases where light shielding properties are imparted to the barrier ribs, there is a tendency for the sensitivity of the photosensitive resin composition to decrease, and as a result, there is a risk that the time required for exposure would increase and productivity would decrease. Thus, a photosensitive resin composition used for forming barrier ribs containing a colorant is required to be highly sensitive.

Patent literature 1 (JP 2001-281440 A) describes a composition in which titanium black is added to a positive tone radiation sensitive resin composition comprising an alkali-soluble resin and a quinone diazide compound as a radiation sensitive resin composition exhibiting high light shielding properties by heat treatment after exposure to light.

Patent Literature 2 (JP 2002-116536 A) describes a method for blackening barrier ribs using carbon black in a radiation sensitive resin composition comprising [A] an alkali-soluble resin, [B] a 1,2-quinone diazide compound, and [C] a colorant.

Patent literature 3 (JP 2010-237310 A) describes a composition in which a heat sensitive dye is added to a positive tone radiation sensitive resin composition comprising an alkali-soluble resin and a quinone diazide compound as a radiation sensitive resin composition exhibiting light shielding properties by heat treatment after exposure to light.

### CITATION LIST

### Patent Literature

[PTL 1] JP 2001-281440 A 1

[PTL 2] JP 2002-116536 A 2

[PTL 3] JP 2010-237310 A 3

### SUMMARY

### Technical Problem

In order to sufficiently enhance the light shielding properties of a cured film of a photosensitive resin composition used for forming a colored barrier rib, a substantial amount of colorant is required. When such a substantial amount of colorant is used, since radiation applied to a coating of the photosensitive resin composition is absorbed by the colorant, the effective strength of the radiation in the coating is notably diminished at the lower portion of the coating (the side close to the substrate), the photosensitive resin composition is not sufficiently exposed to light (photosensitive inhibition) and as a result, pattern formability is impaired.

In the formation of barrier ribs for organic EL elements, it is important for the material that forms the barrier ribs to be highly sensitive from the viewpoint of productivity. However, when a black photosensitive resin composition containing a colorant is used, insufficient exposure occurs under normally used exposure conditions and it is necessary, for example, to extend exposure time, which is a factor in reducing productivity.

In general, an ultra-high pressure mercury lamp that emits g-rays (wavelength 436 nm), h-rays (wavelength 405 nm) and i-rays (wavelength 365 nm) is used for the purpose of organic EL element barrier ribs wherein the g-, h- and i-rays are used for exposure. However, due to restrictions on the facilities and equipment of manufacturers, there is a demand for the use of only i-rays. Since the total amount of energy irradiated is smaller when only i-rays are used for exposure, there is a risk that the reaction rate of a radiation sensitive compound, for example, a photoacid generator, will decrease and, in the development step, there is a risk that insoluble binder resin residue may be generated or a reduction in pattern formability may occur. Thus, it is desirable to further enhance the sensitivity of a colorant-containing photosensitive resin composition and increase the flexibility in the use of radiation for exposure.

It is an object of the present invention to reduce photosensitive inhibition of a photosensitive resin composition containing a black dye to improve pattern formability and enhance sensitivity.

### Solution to Problem

The present inventors have found that, by adding a dye other than black to a photosensitive resin composition containing a black dye as a colorant, the content of the black dye can be reduced with keeping the light shielding properties of the photosensitive resin composition, so that the pattern formability of the photosensitive resin composition can be improved and the sensitivity can be enhanced.

Specifically, the present invention includes the following aspects.
[1] A photosensitive resin composition comprising

a binder resin (A);

a radiation sensitive compound (B); and

a dye (C),

wherein the dye (C) comprises a black dye (C1) and a dye (C2) other than (C1), wherein the dye (C2) has the absorption maximum at a wavelength from 480 to 550 nm in the wavelength range of 300 to 800 nm, and wherein Abs2/Abs1 is 0.1 to 1.0 when the absorbance at the wavelength of the absorption maximum of the dye (C2) is taken as Abs1 and the average absorbance over the range of 560 to 600 nm wavelength is taken as Abs2.
[2] The photosensitive resin composition according to [1], wherein Abs4/Abs3 is 0.8 to 1.6 when the average absorbance over the range of 450 to 545 nm wavelength is taken as Abs3 and the average absorbance over the range of 550 to 650 nm wavelength is taken as Abs4 in the absorbance curve of the photosensitive resin composition.
[3] The photosensitive resin composition according to [1] or [2], wherein the absorbance at 365 nm wavelength of the dye (C2) is 0 to 80 when the absorbance at the wavelength of the absorption maximum of the dye (C2) in the wavelength range of 300 to 800 nm is 100.
[4] The photosensitive resin composition according to any one of [1] to [3], wherein the photosensitive resin composition comprises 50 to 95% by mass of the black dye (C1) with respect to the total mass of the dye (C).
[5] The photosensitive resin composition according to any one of [1] to [4], wherein the dye (C2) is a red dye.
[6] The photosensitive resin composition according to any one of [1] to [5], wherein the photosensitive resin composition comprises 5 to 35% by mass of the dye (C2) with respect to the total mass of the dye (C).
[7] The photosensitive resin composition according to any one of [1] to [6], wherein the color index of the black dye (C1) is 7 to 47.
[8] The photosensitive resin composition according to any one of [1] to [7], wherein the radiation sensitive compound (B) is at least one photoacid generator selected from the group consisting of quinone diazide compounds, sulfonium salts, phosphonium salts, diazonium salts, and iodonium salts.
[9] The photosensitive resin composition according to [8], comprising 5 parts by mass to 50 parts by mass of the photoacid generator with respect to 100 parts by mass of the total of the binder resin (A), the radiation sensitive compound (B), and the dye (C).
[10] The photosensitive resin composition according to any one of [1] to [9], wherein the binder resin (A) has an alkali-soluble functional group.
[11] The photosensitive resin composition according to any one of [1] to [10], comprising 15 parts by mass to 50 parts by mass of the dye (C) with respect to 100 parts by mass of the total of the binder resin (A), the radiation sensitive compound (B), and the dye (C).
[12] The photosensitive resin composition according to any one of to [11], wherein the binder resin (A) is at least one selected from the group consisting of:

(a) a polyalkenylphenolic resin having a structural unit represented by formula (1)

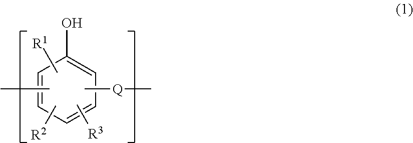

wherein in formula (1), R¹, R² and R³ each independently represent a hydrogen atom; an alkyl group having 1 to 5 carbon atoms; an alkenyl group represented by formula (2)

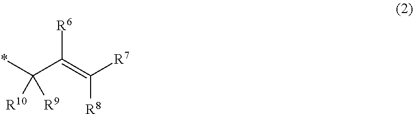

wherein in formula (2), R⁶, R⁷, R⁸, R⁹ and R¹⁰ each independently represent a hydrogen atom, an alkyl group having 1 to 5 carbon atoms, a cycloalkyl group having 5 to 10 carbon atoms, or an aryl group having 6 to 12 carbon atoms, * in formula (2) represents a bonding site with a carbon atom constituting the aromatic ring; an alkoxy group having 1 to 2 carbon atoms; or a hydroxy group, and at least one of R¹, R² and R³ is the alkenyl group represented by formula (2), Q is an alkylene group represented by the formula —CR⁴R⁵—, a cycloalkylene group having 5 to 10 carbon atoms, a divalent organic group having an aromatic ring, a divalent organic group having an alicyclic fused ring, or a divalent group consisting of a combination thereof, R⁴ and R⁵ each independently represent a hydrogen atom, an alkyl group having 1 to 5 carbon atoms, an alkenyl group having 2 to 6 carbon atoms, a cycloalkyl group having 5 to 10 carbon atoms, or an aryl group having 6 to 12 carbon atoms;

(b) a hydroxypolystyrene resin derivative having a structural unit represented by formula (3)

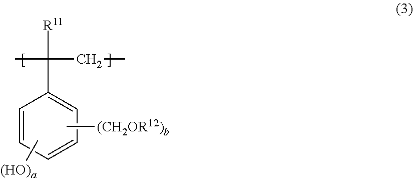

wherein in formula (3), R¹¹ represents a hydrogen atom or an alkyl group having 1 to 5 carbon atoms, a is an integer from 1 to 4, b is an integer from 1 to 4, a+b is in the range of 2 to 5, and R¹² is at least one selected from the group consisting of a hydrogen atom, a methyl group, an ethyl group, and a propyl group;

(c) an aqueous alkaline solution-soluble resin having an epoxy group and a phenolic hydroxy group; and

(d) an aqueous alkaline solution-soluble copolymer of a polymerizable monomer having an alkali-soluble functional group and an additional polymerizable monomer.
[13] The photosensitive resin composition according to any one of [1] to [11], wherein the binder resin (A) is at least one selected from the group consisting of:

(c) an aqueous alkaline solution-soluble resin having an epoxy group and a phenolic hydroxy group; and

(d) an aqueous alkaline solution-soluble copolymer of a polymerizable monomer having an alkali-soluble functional group and an additional polymerizable monomer.
[14] An organic EL element barrier rib comprising a cured product of the photosensitive resin composition according to any one of [1] to [13].
[15] An organic EL element insulating film comprising a cured product of the photosensitive resin composition according to any one of [1] to [13].
[16] An organic EL element comprising a cured product of the photosensitive resin composition according to any one of [1] to [13].

### Advantageous Effects of Invention

According to the present invention, photosensitive inhibition of a photosensitive resin composition containing a black dye can be reduced to improve pattern formability and enhance sensitivity.

### BRIEF DESCRIPTION OF DRAWINGS

FIG. 1 shows absorbance curves of VALIFAST (trademark) BLACK 3804, and VALIFAST (trademark) RED 3312.

FIG. 2 shows absorbance curves of VALIFAST (trademark) ORANGE 3209, VALIFAST (trademark) BROWN 3405, and VALIFAST (trademark) BLUE 2602.

### DESCRIPTION OF EMBODIMENTS

The present invention will be described in detail below.

In the present disclosure, “alkali-soluble” and “aqueous alkaline solution-soluble” refer to a photosensitive resin composition or a component thereof, or a coating or cured coating of the photosensitive resin composition that can dissolve in an aqueous alkaline solution, for example, an aqueous solution of 2.38% by mass of tetramethylammonium hydroxide. “Alkali-soluble functional group” refers to a group that imparts such alkali-solubility to a photosensitive resin composition or a component thereof, or a coating or cured coating of the photosensitive resin composition.

In the present disclosure, “radical polymerizable functional group” refers to one or more ethylenically unsaturated groups, and “radical polymerizable compound” refers to a compound having one or more ethylenically unsaturated groups.

In the present disclosure, “(meth)acrylic” refers to acrylic or methacrylic, “(meth)acrylate” refers to acrylate or methacrylate, and “(meth)acryloyl” refers to acryloyl or methacryloyl.

In one embodiment, the photosensitive resin composition comprises a binder resin (A), a radiation sensitive compound (B), and a dye (C), and the dye (C) comprises a black dye (C1) and a dye (C2) other than (C1). The dye (C2) has the absorption maximum at a wavelength from 480 to 550 nm in the wavelength range of 300 to 800 nm, and Abs2/Abs1 is 0.1 to 1.0 when the absorbance at the wavelength of the absorption maximum of the dye (C2) is taken as Abs1 and the average absorbance over the range of 560 to 600 nm wavelength is taken as Abs2.

### [Binder Resin (A)]

Binder resin (A) is not particularly limited, but preferably has an alkali-soluble functional group and is alkali soluble. Examples of the alkali-soluble functional group include a carboxy group, a phenolic hydroxy group, a sulfo group, a phosphoric acid group and a mercapto group, but not particularly limited thereto. A binder resin having two or more of alkali-soluble functional groups may be used.

Examples of the binder resin (A) include an acrylic resin, a polystyrene resin, an epoxy resin, a polyamide resin, a phenol resin, a polyimide resin, a polyamic acid resin, a polybenzoxazole resin, a polybenzoxazole resin precursor, a silicone resin, a cyclic olefin polymer, a cardo resin, and derivatives thereof, and resins obtained by bonding an alkali-soluble functional group thereto. A homopolymer or copolymer of a polymerizable monomer having an alkali-soluble functional group may be used as the binder resin (A). These resins may be used alone or in combination of two or more thereof. The binder resin (A) may have a radical polymerizable functional group. In one embodiment, the binder resin (A) has a (meth)acryloyloxy group, an allyl group, or a methallyl group as the radical polymerizable functional group.

In one embodiment, the binder resin (A) comprises at least one selected from the group consisting of resin components (a) to (k) below.

(a) A polyalkenylphenolic resin with a specific structure

(b) A hydroxypolystyrene resin derivative with a specific structure

(c) An aqueous alkaline solution-soluble resin having an epoxy group and a phenolic hydroxy group

(d) An aqueous alkaline solution-soluble copolymer of a polymerizable monomer having an alkali-soluble functional group and an additional polymerizable monomer

(e) A polyimide resin

(f) A polyamic acid resin

(g) A polybenzoxazole resin

(h) A polybenzoxazole resin precursor

(i) A silicone resin

(j) A cyclic olefin polymer

(k) A cardo resin

### (a) Polyalkenylphenolic Resin

A polyalkenylphenolic resin (a) can be obtained by subjecting a hydroxy group of a known phenolic resin to alkenyl etherification, and further subjecting an alkenyl ether group to Claisen rearrangement. In particular, a polyalkenylphenolic resin having a structural unit represented by formula (1) is preferable.

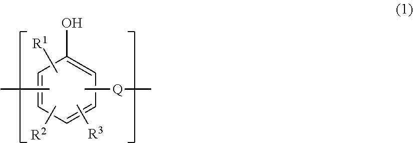

By including such a resin, the development characteristics are improved and outgassing can be reduced in the obtained photosensitive resin composition.

In Formula (1), R¹, R² and R³ each independently represent a hydrogen atom, an alkyl group having 1 to 5 carbon atoms; an alkenyl group represented by formula (2)

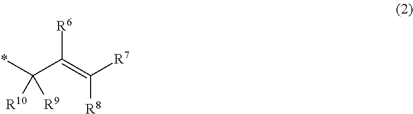

wherein in formula (2), R⁶ R⁷, R⁸, R⁹ and R¹⁰ each independently represent a hydrogen atom, an alkyl group having 1 to 5 carbon atoms, a cycloalkyl group having 5 to 10 carbon atoms, or an aryl group having 6 to 12 carbon atoms, * in formula (2) represents a bonding site with a carbon atom constituting the aromatic ring; an alkoxy group having 1 to 2 carbon atoms; or a hydroxy group, and at least one of R¹, R² and R³ is the alkenyl group represented by formula (2), Q is an alkylene group represented by the formula —CR⁴R⁵—, a cycloalkylene group having 5 to 10 carbon atoms, a divalent organic group having an aromatic ring, a divalent organic group having an alicyclic fused ring, or a divalent group consisting of a combination thereof, R⁴ and R⁵ each independently represent a hydrogen atom, an alkyl group having 1 to 5 carbon atoms, an alkenyl group having 2 to 6 carbon atoms, a cycloalkyl group having 5 to 10 carbon atoms, or an aryl group having 6 to 12 carbon atoms. When two or more structural units represented by formula (1) are present in one molecule, the structural units represented by formula (1) may be the same or different for each one.

In formula (1), R¹, R², and R³ each independently represent a hydrogen atom, an alkyl group having 1 to 5 carbon atoms, an alkenyl group represented by formula (2), an alkoxy group having 1 to 2 carbon atoms, or a hydroxy group, and at least one of R¹, R² and R³ the alkenyl group represented by formula (2). Specific examples of the alkyl group having 1 to 5 carbon atoms represented by R¹, R² or R³ of formula (1) include a methyl group, an ethyl group, an n-propyl group, an isopropyl group, an n-butyl group, a sec-butyl group, a tert-butyl group, and an n-pentyl group. Specific examples of the alkoxy group having 1 to 2 carbon atoms include a methoxy group and an ethoxy group.

R⁶, R⁷, R⁸, R⁹ and R¹⁰ of the alkenyl group represented by formula (2) each independently represent a hydrogen atom, an alkyl group having 1 to 5 carbon atoms, a cycloalkyl group having 5 to 10 carbon atoms, or an aryl group having 6 to 12 carbon atoms. Specific examples of the alkyl group having 1 to 5 carbon atoms include a methyl group, an ethyl group, an n-propyl group, an isopropyl group, an n-butyl group, a sec-butyl group, a tert-butyl group, and an n-pentyl group. Examples of the cycloalkyl group having 5 to 10 carbon atoms include a cyclopentyl group, a cyclohexyl group, a methylcyclohexyl group, and a cycloheptyl group. Specific examples of the aryl group having 6 to 12 carbon atoms include a phenyl group, a methylphenyl group, an ethylphenyl group, a biphenyl group, and a naphthyl group. It is preferable that R⁶, R⁷, R⁸, R⁹, and R¹⁰ each independently represent a hydrogen atom or an alkyl group having 1 to 5 carbon atoms. The alkenyl group represented by formula (2) is preferably an allyl group or a methallyl group from the viewpoint of reactivity, and more preferably an allyl group.

It is most preferable that any one of R¹, R² and R³ be an allyl group or a methallyl group, and the other two be hydrogen atoms.

Q of formula (1) is an alkylene group represented by the formula —CR⁴R⁵—, a cycloalkylene group having 5 to 10 carbon atoms, a divalent organic group having an aromatic ring, a divalent organic group having an alicyclic fused ring, or a divalent group consisting of a combination thereof. R⁴ and R⁵ each independently represent a hydrogen atom, an alkyl group having 1 to 5 carbon atoms, an alkenyl group having 2 to 6 carbon atoms, a cycloalkyl group having 5 to 10 carbon atoms or an aryl group having 6 to 12 carbon atoms. Specific examples of the alkyl group having 1 to 5 carbon atoms include a methyl group, an ethyl group, an n-propyl group, an isopropyl group, an n-butyl group, a sec-butyl group, a tert-butyl group, and an n-pentyl group. Specific examples of the alkenyl group having 2 to 6 carbon atoms include a vinyl group, an allyl group, a butenyl group, a pentenyl group, and a hexenyl group. Examples of the cycloalkyl group having 5 to 10 carbon atoms include a cyclopentyl group, a cyclohexyl group, a methylcyclohexyl group, and a cycloheptyl group. Specific examples of the aryl group having 6 to 12 carbon atoms include a phenyl group, a methylphenyl group, an ethylphenyl group, a biphenyl group, and a naphthyl group. It is preferable that R⁴ and R⁵ each independently represent a hydrogen atom or an alkyl group having 1 to 3 carbon atoms and it is most preferable for both to be hydrogen atoms.

Specific examples of the cycloalkylene group having 5 to 10 carbon atoms include a cyclopentylene group, a cyclohexylene group, a methylcyclohexylene group, and a cycloheptylene group. Specific examples of the divalent organic group having an aromatic ring include a phenylene group, a tolylene group, a naphthylene group, a biphenylene group, a fluorenylene group, an anthracenylene group, a xylylene group, a 4,4-methylenediphenyl group and a group represented by formula (6).

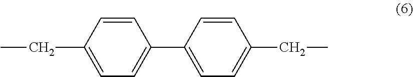 [SMILES: CCc1ccc(-c2ccc(CC)cc2)cc1]

Specific examples of the divalent organic group having an alicyclic fused ring include a dicyclopentadienylene group.

When the polyalkenylphenolic resin (a) is used as the binder resin (A), from the viewpoint of alkali developability and outgassing, a particularly preferable example of the polyalkenylphenolic resin (a) is a polyalkenylphenolic resin having a structural unit represented by formula (1) wherein Q is —CH₂—, i.e., by formula (4).

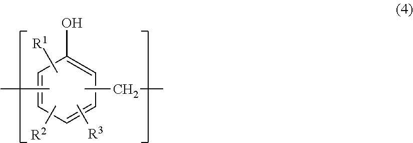

In formula (4), R¹, R² and R³ are the same as in formula (1). Preferable groups for R¹, R² and R³ are the same as those in formula (1).

The structural unit represented by formula (1) or formula (4) is preferably included in the polyalkenylphenolic resin (a) at 50 mol % to 100 mol %, more preferably 70 mol % to 100 mol % and still more preferably 80 mol % to 100 mol %. 50 mol % or more of the structural unit represented by formula (1) or formula (4) in the polyalkenylphenolic resin (a) is favorable in terms of improvement of heat resistance. The phenolic hydroxy group in the polyalkenylphenolic resin (a) ionizes in the presence of a basic compound, and the polyalkenylphenolic resin becomes soluble in water. Thus, the polyalkenylphenolic resin is necessary to have a certain amount of phenolic hydroxy groups from the viewpoint of alkali developability. Accordingly, it is particularly preferable that the polyalkenylphenolic resin (a) having a structural unit represented by formula (4) be a polyalkenylphenolic resin having a structural unit represented by formula (4) and a structural unit represented by formula (7).

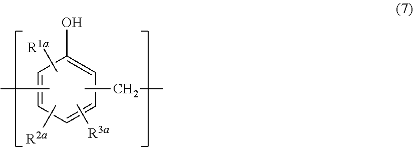

In formula (7), R^{1a}, R^{2a}, and R^{3a} each independently represent a hydrogen atom or an alkyl group having 1 to 5 carbon atoms. Preferable groups for R^{1a}, R^{2a}, and R^{3a} are the same as those for R¹, R², and R³ in formula (1).

In the polyalkenylphenolic resin (a) having structural unit represented by formula (4) and a structural unit represented by formula (7), when x is the number of structural units represented by formula (4) and y is the number of structural units represented by formula (7), then 0.5≤x/(x+y)<1, and 0<y/(x+y)≤0.5, and x+y is preferably 2 to 50, more preferably 3 to 40, and still more preferably 5 to 25.

When the polyalkenylphenolic resin (a) is used as the binder resin (A), the number average molecular weight of the polyalkenylphenolic resin (a) is preferably 500 to 5,000, more preferably 800 to 3,000, and still more preferably 900 to 2,000. The weight average molecular weight of the polyalkenylphenolic resin (a) is preferably 500 to 30,000, more preferably 3,000 to 25,000, and still more preferably 5,000 to 20,000. When the number average molecular weight is 500 or more or the weight average molecular weight is 500 or more, the rate of alkali development is suitable, and since the difference in dissolution rate between the exposed parts and the unexposed parts is sufficient, pattern resolution is favorable, and when the number average molecular weight is 5,000 or less or the weight average molecular weight is 30,000 or less, the alkali developability is favorable. In the present disclosure, the number average molecular weight and the weight average molecular weight of the binder resin (A) are measured by gel permeation chromatography (GPC) in terms of standard polystyrene equivalents.

### (b) Hydroxypolystyrene Resin Derivative

A hydroxypolystyrene resin derivative (b) having a structural unit represented by formula (3) can be used as the binder resin (A).

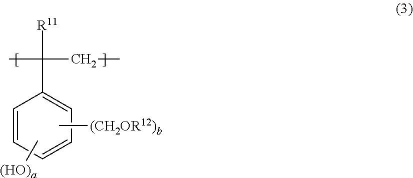

The inclusion of such a resin improves the development characteristics of the obtained photosensitive resin composition and can also contribute to the reduction of outgassing thereof.

In formula (3), R¹¹ represents a hydrogen atom or an alkyl group having 1 to 5 carbon atoms, a is an integer from 1 to 4, b is an integer from 1 to 4, a+b is in the range of 2 to 5, and R¹² is at least one selected from the group consisting of a hydrogen atom, a methyl group, an ethyl group, and a propyl group.

When the hydroxypolystyrene resin derivative (b) is used as the binder resin (A), a copolymer having a structural unit represented by formula (3) and a structural unit represented by formula (5) is preferable from the viewpoint of alkali developability and outgassing.

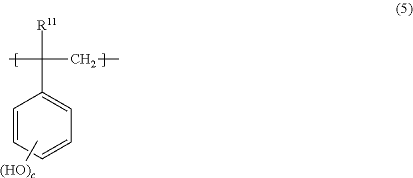

In formula (5), R¹³ represents a hydrogen atom or an alkyl group having 1 to 5 carbon atoms and c is an integer from 1 to 5.

The hydroxypolystyrene resin derivative (b) having a structural unit represented by formula (3) and the hydroxypolystyrene resin derivative (b) having a structural unit represented by formula (3) and a structural unit represented by formula (5) can be obtained by, for example, polymerizing, using a publicly-known method, one or more phenolic hydroxy group-containing aromatic vinyl compounds, such as p-hydroxystyrene, m-hydroxystyrene, o-hydroxystyrene, p-isopropenylphenol, m-isopropenylphenol, and o-isopropenylphenol, then reacting a portion of the obtained polymer or copolymer with formaldehyde using a publicly-known method, for example, the method disclosed in JP 2013-151705 A, or by further reacting with an alcohol.

p-Hydroxystyrene or m-hydroxystyrene may be preferably used as the phenolic hydroxy group-containing aromatic vinyl compound.

When the hydroxypolystyrene resin derivative (b) is used as the binder resin (A), the number average molecular weight of the hydroxypolystyrene resin derivative (b) is preferably 1,000 to 20,000, more preferably 3,000 to 10,000, and still more preferably 4,000 to 9,000. The weight average molecular weight of the hydroxypolystyrene resin derivative (b) is preferably 1,000 to 100,000, more preferably 5,000 to 75,000, and still more preferably 10,000 to 50,000. When the number average molecular weight is 1,000 or more or the weight average molecular weight is 1,000 or more, the use of the resin as a photosensitive material is favorable since the alkali solubility is suitable, and when the number average molecular weight is 20,000 or less or the weight average molecular weight is 100,000 or less, the coatability and developability are favorable.

### (c) Aqueous Alkaline Solution-Soluble Resin Having an Epoxy Group and a Phenolic Hydroxy Group

An aqueous alkaline solution-soluble resin having an epoxy group and a phenolic hydroxy group (c) may be used as the binder resin (A). Such an aqueous alkaline solution-soluble resin (c) can be obtained by, for example, reacting an epoxy group of a compound having at least two epoxy groups per molecule (hereinafter may be referred to as “epoxy compound”) with the carboxy group of a hydroxybenzoic acid compound. By having epoxy groups in the aqueous alkaline solution-soluble resin (c), crosslinking is formed during heating by reacting the epoxy groups with a phenolic hydroxy group, so that the chemical resistance, heat resistance, etc., of a coating can be improved. The phenolic hydroxy groups contribute to solubility in an aqueous alkaline solution during development.

The following reaction formula 1 is an example of the reaction between one epoxy group of an epoxy compound and the carboxy group of a hydroxybenzoic acid compound to form a phenolic hydroxy group-containing compound.

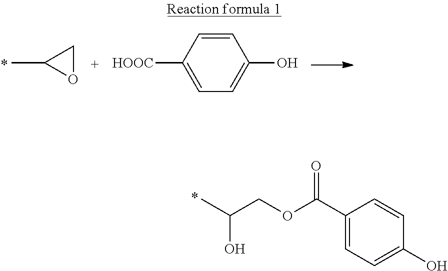

Examples of the compound having at least two epoxy groups per molecule may include a phenol novolak epoxy resin, a cresol novolak epoxy resin, a bisphenol epoxy resin, a biphenol epoxy resin, a naphthalene skeleton-containing epoxy resin, an alicyclic epoxy resin, and a heterocyclic epoxy resin. These epoxy compounds are acceptable provided there are at least two epoxy groups per molecule and may be used alone or in combination of two or more thereof. As these are thermosetting compounds, the structures thereof cannot be unambiguously defined due to differences, such as the presence or absence of epoxy groups, the type of functional groups, and the degree of polymerization, as is common knowledge for a person skilled in the art. One example of the structure of the novolak epoxy resin is illustrated in formula (9). In formula (9), R¹⁴ represents, for example, a hydrogen atom, an alkyl group having 1 to 5 carbon atoms, an alkoxy group having 1 to 2 carbon atoms or a hydroxy group, and m is an integer from 1 to 50.

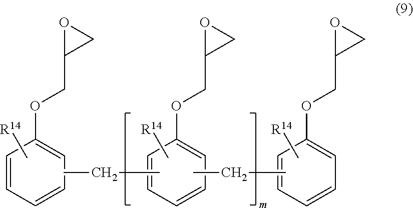

Examples of the phenol novolak epoxy resin include EPICLON (trademark) N-770 (DIC Corporation) and jER (trademark)-152 (Mitsubishi Chemical Corporation). Examples of the cresol novolak epoxy resin include EPICLON (trademark) N-695 (DIC Corporation) and EOCN (trademark)-102S (Nippon Kayaku Co., Ltd.). Examples of the bisphenol epoxy resin include a bisphenol-A epoxy resin, such as jER (trademark) 828, jER (trademark) 1001 (Mitsubishi Chemical Corporation) and YD-128 (trade name, NIPPON STEEL Chemical & Material Co., Ltd.), and a bisphenol-F epoxy resin, such as jER (trademark) 806 (Mitsubishi Chemical Corporation) and YDF-170 (trade name, NIPPON STEEL Chemical & Material Co., Ltd.). Examples of the biphenol epoxy resin include jER (trademark) YX-4000 and jER (trademark) YL-6121H (Mitsubishi Chemical Corporation). Examples of the naphthalene skeleton-containing epoxy resin include NC-7000 (trade name, Nippon Kayaku Co., Ltd.) and EXA-4750 (trade name, DIC Corporation). Examples of the alicyclic epoxy resin include EHPE (trademark)-3150 (Daicel Corporation). Examples of the heterocyclic epoxy resin include TEPIC (trademark), TEPIC (trademark)-L, TEPIC (trademark)-H, and TEPIC (trademark)-S (Nissan Chemical Corporation).

It is preferable that the compound having at least two epoxy groups per molecule be a cresol novolak epoxy resin. The photosensitive resin composition including the aqueous alkaline solution-soluble resin having an epoxy group and a phenolic hydroxy group (c), the resin derived from a cresol novolak epoxy resin, has excellent pattern formability and readily adjustable alkali solubility, and exhibits little outgassing.

The hydroxybenzoic acid compound is a compound in which at least one of positions 2 to 6 of benzoic acid has been substituted with a hydroxy group. Examples thereof include salicylic acid, 4-hydroxybenzoic acid, 2,3-dihydroxybenzoic acid, 2,4-dihydroxybenzoic acid, 2,5-dihydroxybenzoic, acid, 2,6-dihydroxybenzoic acid, 3,4-dihydroxybenzoic acid, 3,5-dihydroxybenzoic acid, 2-hydroxy-5-nitrobenzoic acid, 3-hydroxy-4-nitrobenzoic acid, and 4-hydroxy-3-nitrobenzoic acid. From the viewpoint of enhancing alkali developability, dihydroxybenzoic acid compounds are preferable. These hydroxybenzoic acid compounds may be used alone or in combination of two or more thereof.

In one embodiment, the aqueous alkaline solution-soluble resin having an epoxy group and a phenolic hydroxy group (c) is the reaction product of a compound having at least two epoxy groups per molecule and a hydroxybenzoic acid compound and has a structure represented by formula (8).

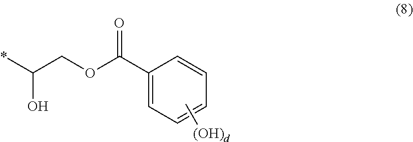

In formula (8), d is an integer from 1 to 5, * represents a bonding site with the residue derived by removing an epoxy group of the compound having at least two epoxy groups per molecule.

In a method for obtaining the aqueous alkaline solution-soluble resin having an epoxy group and a phenolic hydroxy group (c) from an epoxy compound and a hydroxybenzoic acid compound, with respect to one equivalent of epoxy groups of the epoxy compound, 0.2 to 1.0 equivalents, preferably 0.3 to 0.9 equivalents, and more preferably 0.4 to 0.8 equivalents of the hydroxybenzoic acid compound may be used. Sufficient alkali solubility can be attained with 0.2 equivalents or more of the hydroxybenzoic acid compound and the increase in molecular weight due to side reactions can be suppressed with 1.0 equivalents or less.

A catalyst may be used to promote the reaction between the epoxy compound and the hydroxybenzoic acid compound. With respect to 100 parts by mass of the mixture of reactants including the epoxy compound and the hydroxybenzoic acid compound, the amount of catalyst used may be 0.1 to 10 parts by mass. The reaction temperature may be 60 to 150° C. and the reaction time may be 3 to 30 hours. Examples of the catalyst for use in this reaction include triethylamine, benzyldimethylamine, triethylammonium chloride, benzyltrimethylammonium bromide, benzyltrimethyl ammonium iodide, triphenylphosphine, chromium octanoate, and zirconium octanoate.

The aqueous alkaline solution-soluble resin having an epoxy group and a phenolic hydroxy group (c) has a number average molecular weight of preferably 500 to 8,000, more preferably 800 to 6,000, and still more preferably 1,000 to 5,000. When the number average molecular weight is 500 or more, the use of the resin as a photosensitive material is favorable since the alkali solubility is suitable, and when the number average molecular weight is 8,000 or less, the coatability and developability are favorable.

### (d) Aqueous Alkaline Solution-Soluble Copolymer of a Polymerizable Monomer Having an Alkali-Soluble Functional Group and an Additional Polymerizable Monomer

An aqueous alkaline solution-soluble copolymer of a polymerizable monomer having an alkali-soluble functional group and an additional polymerizable monomer (d) may be used as the binder resin (A). Examples of the alkali-soluble functional group include a carboxy group, an alcoholic hydroxy group, a phenolic hydroxy group, a sulfo group, a phosphoric acid group, and an acid anhydride group. Examples of the polymerizable functional group of the polymerizable monomer include a radical polymerizable functional group, such as CH₂═CH—, CH₂═C(CH₃)—, CH₂═CHCO—, CH₂═C(CH₃)CO—, and —OC—CH═CH—CO—.

The aqueous alkaline solution-soluble copolymer of a polymerizable monomer having an alkali-soluble functional group and an additional polymerizable monomer (d) can be produced by, for example, the radical polymerization of a polymerizable monomer having an alkali-soluble functional group and an additional polymerizable monomer. A derivative obtained by synthesizing a copolymer by radical polymerization and thereafter adding an alkali-soluble functional group thereto may be used. Examples of the polymerizable monomer having an alkali-soluble functional group include 4-hydroxystyrene, (meth)acrylic acid, α-bromo(meth)acrylic acid, α-chloro(meth)acrylic acid, β-furyl(meth)acrylic acid, β-styryl(meth)acrylic acid, maleic acid, monomethyl maleate, monoethyl maleate, monoisopropyl maleate, fumaric acid, cinnamic acid, α-cyanocinnamic acid, itaconic acid, crotonic acid, propiolic acid, 4-hydroxyphenyl methacrylate, 3,5-dimethyl-4-hydroxybenzylacrylamide, 4-hydroxyphenylacrylamide, 4-hydroxyphenylmaleimide, 3-maleimidopropionic acid, 4-maleimidobutyric acid, and 6-maleimidohexanoic acid. Examples of the additional polymerizable monomer include styrene derivatives, such as styrene, vinyl toluene, α-methylstyrene, p-methylstyrene, and p-ethylstyrene; acrylamide; acrylonitrile; an ether compound of vinyl alcohol, such as vinyl n-butyl ether; a (meth)acrylic acid ester, such as alkyl (meth)acrylates, tetrahydrofurfuryl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, and isobornyl (meth)acrylate; maleic acid derivatives, such as maleic anhydride, and a maleic acid monoester; and an N-substituted maleimide, such as phenylmaleimide, and cyclohexylmaleimide. From the viewpoint of heat resistance, the aqueous alkaline solution-soluble copolymer of a polymerizable monomer having an alkali-soluble functional group and an additional polymerizable monomer (d) preferably has one or more cyclic structures, such as an alicyclic structure, an aromatic structure, a polycyclic structure, an inorganic cyclic structure, or a heterocyclic structure.

The polymerizable monomer having an alkali-soluble functional group preferably forms a structural unit represented by formula (10).

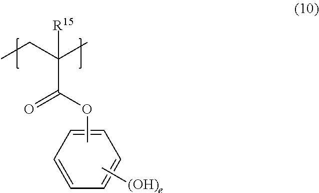

In formula (10), R¹⁵ represents a hydrogen atom or an alkyl group having 1 to 5 carbon atoms and e is an integer from 1 to 5. 4-Hydroxyphenyl methacrylate is particularly preferable as the polymerizable monomer haying an alkali-soluble functional group.

Examples of the additional polymerizable monomer include styrene derivatives, such as styrene, vinyl toluene, α-methylstyrene, p-methylstyrene, and p-ethylstyrene; acrylamide; acrylonitrile; an ether compound of vinyl alcohol, such as vinyl n-butyl ether; a (meth)acrylic acid ester, such as alkyl (meth)acrylates, tetrahydrofurfuryl (meth)acrylate, dimethylaminoethyl (meth)acrylate, diethylaminoethyl (meth)acrylate, glycidyl (meth)acrylate, 2,2,2-trifluoroethyl (meth)acrylate, 2,2,3,3-tetrafluoropropyl (meth)acrylate, and isobornyl(meth)acrylate; maleic acid derivatives, such as maleic anhydride, and a maleic acid monoester; and an N-substituted maleimide, such as phenylmaleimide, and cyclohexylmaleimide. Among them, a polymerizable monomer forming a structural unit represented by formula (11) is preferable.

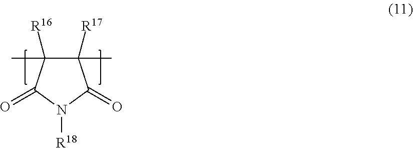

In formula (11), R¹⁶ and R¹⁷ each independently represent a hydrogen atom, an alkyl group having 1 to 3 carbon atoms, a fully or partially fluorinated alkyl group having 1 to 3 carbon atoms, or a halogen atom. R¹⁸ represents a hydrogen atom, a linear or cyclic alkyl group having 1 to 6 carbon atoms, or a phenyl group, or represents a phenyl group substituted with at least one selected from the group consisting of a hydroxy group, an alkyl group having 1 to 6 carbon atoms, and an alkoxy group haying 1 to 6 carbon atoms. It is preferable that R¹⁶ and R¹⁷ be hydrogen atoms. It is preferable that R¹⁸ be a cyclic alkyl group having 1 to 6 carbon atoms or a phenyl group. Among such additional polymerizable monomers, phenylmaleimide and cyclohexylmaleimide are particularly preferable.

In one embodiment, the aqueous alkaline solution-soluble copolymer of a polymerizable monomer having an alkali-soluble functional group and an additional polymerizable monomer (d) has a structural unit represented by formula (10)

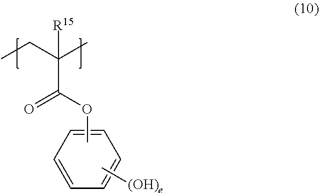

wherein in formula (10), R¹⁵ is a hydrogen atom or an alkyl group having 1 to 5 carbon atoms and e is an integer from 1 to 5, and
a structural unit represented by formula (11)

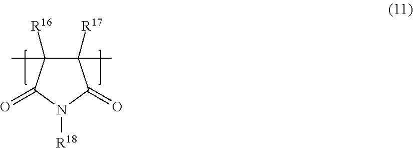

wherein in formula (11), R¹⁶ and R¹⁷ each independently represent a hydrogen atom, an alkyl group having 1 to 3 carbon atoms, a fully or partially fluorinated alkyl group having 1 to 3 carbon atoms, or a halogen atom, and R¹⁸ represents a hydrogen atom, a linear or cyclic alkyl group having 1 to 6 carbon atoms or a phenyl group, or represents a phenyl group substituted with at least one selected from the group consisting of a hydroxy group, an alkyl group having 1 to 6 carbon atoms, and an alkoxy group having 1 to 6 carbon atoms.

The use of 4-hydroxyphenyl methacrylate as the polymerizable monomer having an alkali-soluble functional group together with the use of phenylmaleimide or cyclohexylmaleimide as the additional polymerizable monomer is particularly preferable. By using a resin in which these polymerizable monomers are radically polymerized, the shape retainability and developability can be improved and outgassing can be reduced.

A polymerization initiator used when producing the aqueous alkaline solution-soluble copolymer of a polymerizable monomer having an alkali-soluble functional group and an additional polymerizable monomer (d) by radical polymerization may be, but not limited to, an azo polymerization initiator, such as 2,2′-azobisisobutyronitrile, 2,2′-azobis(2-methylbutyronitrile), dimethyl 2,2′-azobis(2-methylpropionate), 4,4′-azobis(4-cyanovaleric acid), and 2,2′-azobis(2,4-dimethylvaleronitrile) (AVN); a peroxide polymerization initiator with a 10 hour half-life temperature of 100 to 170° C., such as dicumyl peroxide, 2,5-dimethyl-2,5-di(tert-butylperoxy)hexane, tert-butylcumyl peroxide, di-tert-butyl peroxide, 1,1,3,3-tetramethyl butyl hydroperoxide, and cumene hydroperoxide; or a peroxide polymerization initiator, such as benzoyl peroxide, lauroyl peroxide, 1,1′-di(tert-butylperoxy)cyclohexane, and tert-butyl peroxypivalate. The amount of the polymerization initiator used with respect to 100 parts by mass of the polymerizable monomer mixture is, in general, preferably 0.01 parts by mass or more, 0.05 parts by mass or more, or 0.5 parts by mass or more, and 40 parts by mass or less, 20 parts by mass or less, or 15 parts by mass or less.

A RAFT (Reversible Addition Fragmentation Transfer) agent may be used in combination with the polymerization initiator. The RAFT agent used may be, but is not limited to, a thiocarbonylthio compound, such as a dithioester, a dithiocarbamate, a trithiocarbonate, and a xanthate. With respect to 100 parts by mass of the total of the polymerizable monomers, the RAFT agent may be used in the range of 0.005 to 20 parts by mass, and preferably in the range of 0.01 to 10 parts by mass.

The weight average molecular weight (Mw) of the aqueous alkaline solution-soluble copolymer of a polymerizable monomer having an alkali-soluble functional group and an additional polymerizable monomer (d) may be 3,000 to 80,000, preferably 4,000 to 70,000, and more preferably 5,000 to 60,000. The number average molecular weight (Mn) may be 1,000 to 30,000, preferably 1,500 to 25,000, and more preferably 2,000 to 20,000. The polydispersity index (Mw/Mn) may be 1.0 to 3.5, preferably 1.1 to 3.0, and more preferably 1.2 to 2.8. When the weight average molecular weight, the number average molecular weight, and the polydispersity index are within the aforementioned ranges, a photosensitive resin composition with excellent alkali solubility and developability can be obtained.

In the present disclosure, if the aqueous alkaline solution-soluble copolymer of a polymerizable monomer having an alkali-soluble functional group and an additional polymerizable monomer (d) also corresponds to the hydroxypolystyrene resin derivative (b), the same is considered as the aqueous alkaline solution-soluble copolymer of a polymerizable monomer having an alkali-soluble functional group and an additional polymerizable monomer (d). If the aqueous alkaline solution-soluble copolymer of a polymerizable monomer having an alkali-soluble functional group and an additional polymerizable monomer (d) also corresponds to the aqueous alkaline solution-soluble resin having an epoxy group and a phenolic hydroxy group (c), the same is considered as the aqueous alkaline solution-soluble copolymer of a polymerizable monomer having an alkali-soluble functional group and an additional polymerizable monomer (d). In other words, the hydroxypolystyrene resin derivative (b) and the aqueous alkaline solution-soluble resin having an epoxy group and a phenolic hydroxy group (c) exclude those that correspond to the aqueous alkaline solution soluble copolymer of a polymerizable monomer having an alkali-soluble functional group and an additional polymerizable monomer (d).

### (e) Polyimide Resin, (f) Polyamic Acid Resin, (g) Polybenzoxazole Resin and (h) Polybenzoxazole Resin Precursor

In one embodiment, the binder resin (A) is at least one selected from the group consisting of a polyimide resin (e), a polyamic acid resin (f), a polybenzoxazole resin (g), and a polybenzoxazole resin precursor (h). The dehydration and ring closure of the polyamic acid resin (f) results in the formation of a resin having a polyimide structure. The dehydration and ring closure of the polybenzoxazole resin precursor (h) results in the formation of a polybenzoxazole resin (g).

The polyimide resin (e) has a structural unit represented by formula (12). The polyamic acid resin (f) and the polybenzoxazole resin precursor (h) have a structural unit represented by formula (13). The polybenzoxazole resin (g) has a structural unit represented by formula (14). The polyimide resin (e) may have both a structural unit represented by formula (12) and a structural unit represented by formula (13), and the polybenzoxazole resin (g) may have both a structural unit represented by formula (14) and a structural unit represented by formula (13).

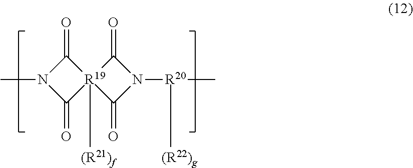

In formula (12), R¹⁹ represents a 4 to 10 valence organic group, R²⁰ represents a 2 to 8 valence organic group, and R²¹ and R²² each independently represent a hydroxy group, a carboxy group, a sulfo group or a mercapto group, and f and g are each independently an integer from 0 to 6.

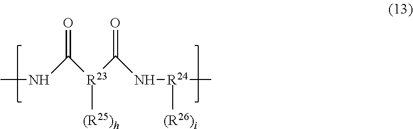

In formula (13), R²³ represents a 2 to 8 valence organic group, R²⁴ represents a 2 to 8 valence organic group, R²⁵ and R²⁶ each independently represent a hydroxy group, a sulfo group, a mercapto group, or —COOR²⁷ where R²⁷ represents a hydrogen atom or a monovalent hydrocarbon group having 1 to 20 carbon atoms, and h and i are each independently an integer from 0 to 6, provided that h+i>0. In the case of the polyamic acid resin (f), h is an integer of 1 or more and at least one R²⁵ is —COOR²⁷. In the case of the polybenzoxazole resin precursor (h), i is an integer of 1 or more and at least one R²⁶ is a phenolic hydroxy group.

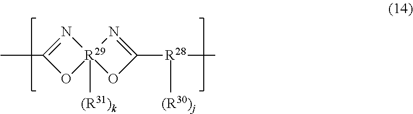

In formula (14), R²⁸ represents a 2 to 8 valence organic group. R²⁹ represents a 2 to 8 valence organic group, and R³⁰ and R³¹ each independently represent a hydroxy group, a carboxy group, a sulfo group or a mercapto group, and j and k are each independently an integer from 0 to 6.

R¹⁹—(R²¹)_{f} of formula (12) represent an acid dianhydride residue. R¹⁹ is a 4 to 10 valence organic group and is preferably an aromatic ring- or cyclic aliphatic group-containing organic group having 5 to 40 carbon atoms.

Examples of the acid dianhydride include: an aromatic tetracarboxylic acid dianhydride, such as pyromellitic dianhydride, 3,3′,4,4′-biphenyltetracarboxylic acid dianhydride, 2,3,3′,4′-biphenyltetracarboxylic acid dianhydride, 2,2′,3,3′-biphenyltetracarboxylic acid dianhydride, 3,3′,4,4-benzophenonetetracarboxylic acid dianhydride, 2,2′,3,3′-benzophenonetetracarboxylic acid dianhydride, 2,2-bis(3,4-dicarboxyphenyl)propane dianhydride, 2,2-bis(2,3-dicarboxyphenyl)propane dianhydride, 1,1-bis(3,4-dicarboxyphenyl)ethane dianhydride, 1,1-bis(2,3-dicarboxyphenyl)ethane dianhydride, bis(3,4-dicarboxyphenyl)methane dianhydride, bis(2,3-dicarboxyphenyl)methane dianhydride, bis(3,4-dicarboxyphenyl) ether dianhydride, 1,2,5,6-naphthalenetetracarboxylic acid dianhydride, 9,9-bis(3,4-dicarboxyphenyl)fluorene dianhydride, 9,9-bis[4-(3,4-dicarboxyphenoxy)phenyl]fluorene dianhydride, 2,3,6,7-naphthalenetetracarboxylic acid dianhydride, 2,3,5,6-pyridinetetracarboxylic acid dianhydride, 3,4,9,10-perylenetetracarboxylic acid dianhydride, and 2,2-bis(3,4-dicarboxyphenyl)hexafluoropropane dianhydride; an aliphatic tetracarboxylic acid dianhydride, such as butanetetracarboxylic acid dianhydride, and 1,2,3,4-cyclopentanetetracarboxylic acid dianhydride; and a combination of two or more thereof.

R²³—(R²³)ₕ of formula (13) and R²⁸—(R³⁰)ⱼ of formula (14) each represent an acid residue. R²³ and R²⁸ each independently represent a 2 to 8 valence organic group and are each preferably an aromatic ring- or cyclic aliphatic group-containing organic group having 5 to 40 carbon atoms.

Examples of the acid include: an aromatic dicarboxylic acid, such as terephthalic acid, isophthalic acid, diphenyl ether dicarboxylic acid, bis(carboxyphenyl)hexafluoropropane, biphenyl dicarboxylic acid, benzophenone dicarboxylic acid, and triphenyl dicarboxylic acid; an aromatic tricarboxylic acid, such as trimellitic acid, trimesic acid, diphenyl ether tricarboxylic acid, and biphenyl tricarboxylic acid; an aromatic tetracarboxylic acid, such as pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2′,3,3′-benzophenonetetracarboxylic acid, 2,2-bis(3,4-dicarboxyphenyl)hexafluoropropane, 2,2-bis(2,3-dicarboxyphenyl)hexafluoropropane, 1,1-bis(3,4-dicarboxyphenyl)ethane, 1,1-bis(2,3-dicarboxyphenyl)ethane, bis(3,4-dicarboxyphenyl)methane, bis(2,3-dicarboxyphenyl)methane, bis(3,4-dicarboxyphenyl) ether, 1,2,5,6-naphthalenetetracarboxylic acid, 2,3,6,7-naphthalenetetracarboxylic acid, 2,3,5,6-pyridinetetracarboxylic acid, and 3,4,9,10-perylenetetracarboxylic acid; and an aliphatic tetracarboxylic acid, such as butanetetracarboxylic acid, and 1,2,3,4-cyclopentanetetracarboxylic acid; and a combination of two or more thereof. In the aforementioned tricarboxylic acids and tetracarboxylic acids, one or two carboxy groups correspond to R²⁵ of formula (13) or R³⁰ of formula (14). These acids may be in the form of an ester or acid anhydride.

R²⁰—(R²²)_{g} of formula (12), R²⁴—(R²⁶)ᵢ of formula (13), and R²⁹—(R³¹)ₖ of formula (14) each represent a diamine residue. R²⁰, R²⁴ and R²⁹ each independently represent a 2 to 8 valence organic group, and preferably an aromatic ring- or cyclic aliphatic group-containing organic group having 5 to 40 carbon atoms.

Examples of the diamine corresponding to R²⁰ of formula (12), or R²⁴ of formula (13) in relation to the polyamic acid resin (f) include: an aromatic diamine, such as 3,4′-diaminodiphenyl ether, 4,4′-diaminodiphenyl ether, 3,4′-diaminodiphenylmethane, 4,4′-diaminodiphenylmethane, 1,4-bis(4-aminophenoxy)benzene, benzidine, m-phenylenediamine, p-phenylenediamine, 1,5-naphthalenediamine, 2,6-naphthalenediamine, bis(4-aminophenoxy)biphenyl, bis[4-(4-aminophenoxy)phenyl] ether, 1,4-bis(4-aminophenoxy)benzene, 2,2′-dimethyl-4,4′-diaminobiphenyl, 2,2′-diethyl-4,4′-diaminobiphenyl, 3,3′-dimethyl-4,4′-diaminobiphenyl, 3,3′-diethyl-4,4′-diaminobiphenyl, 2,2′,3,3′-tetramethyl-4,4′-diaminobiphenyl, 3,3′,4,4′-tetramethyl-4,4′-diaminobiphenyl, 2,2′-di(trifluoromethyl)-4,4′-diaminobiphenyl, and 9,9-bis(4-aminophenyl)fluorene, and a compound obtained by substituting at least one hydrogen atom on the aromatic ring of the aromatic diamine with an alkyl group or a halogen atom; an aliphatic diamine, such as cyclohexyldiamine and methylene biscyclohexyl amine; and a combination of two or more thereof.

Examples of the diamine corresponding to R²⁴ of formula (13) in relation to the polybenzoxazole resin precursor (h), or R²⁹ of formula (14) include a bisaminophenol compound having a phenolic hydroxy group at the ortho position with respect to the amino group on the aromatic ring of the aforementioned aromatic diamine, and a combination of two or more thereof.

The terminals of the polyimide resin (e), the polyamic acid resin (f), the polybenzoxazole resin (g), and the polybenzoxazole resin precursor (h) may be capped with a monoamine, acid anhydride, acid chloride or monocarboxylic acid having an acidic group so that these resins have an acidic group at the terminal of the main chain thereof.

The polyamic acid resin (f) may be synthesized by, for example: a method in which a tetracarboxylic acid dianhydride and a diamine are reacted; a method in which a diester is formed from a tetracarboxylic acid dianhydride and an alcohol and thereafter the diester is reacted with a diamine in the presence of a condensing agent; or a method in which a diester is formed from a tetracarboxylic acid dianhydride and an alcohol, the remaining dicarboxylic acid is reacted to form an acid chloride, and the obtained intermediate is reacted with a diamine.

The polybenzoxazole resin precursor (h) can be synthesized by, for example, a condensation reaction in which a bisaminophenol compound is reacted with a poly carboxylic acid, such as a dicarboxylic acid, a tricarboxylic acid, or a tetracarboxylic acid. Specific examples include: a method in which an intermediate obtained by reacting a dehydrating condensing agent, such as dicyclohexyl carbodiimide (DCC), with a polycarboxylic acid, is reacted with a bisaminophenol compound; and a method in which a dicarboxylic acid dichloride solution is added dropwise to a solution of a bisaminophenol compound to which a tertiary amine, such as pyridine, has been added.

The polyimide resin (e) can be synthesized by, for example, the dehydration and ring closure of the polyamic acid resin (f), which has been obtained by the aforementioned method, by heating or chemical treatment with an acid or a base.

The polybenzoxazole resin (g) can be synthesized by, for example, the dehydration and ring closure of the polybenzoxazole resin precursor (h), which has been obtained by the aforementioned method, by heating or chemical treatment with an acid or a base.

The number average molecular weights of the polyimide resin (e), the polyamic acid resin (f), the polybenzoxazole resin (g), and the polybenzoxazole resin precursor (h) are each preferably 500 to 8,000, more preferably 800 to 6,000, and still more preferably 1,000 to 5,000. When the number average molecular weight is 500 or more, the use of the resin as a photosensitive material is favorable since the alkali solubility is suitable, and when the number average molecular weight is 8,000 or less, the coatability and developability are favorable.

### (i) Silicone Resin

In one embodiment, the binder resin (A) includes a silicone resin (i). The silicone resin (i) can be synthesized by the hydrolytic condensation of at least one compound selected from the group consisting of an organosilane represented by formula (15) and an organosilane represented by formula (16). By using the organosilanes represented by formula (15) and formula (16), a photosensitive resin composition with excellent sensitivity and resolution can be obtained.

The organosilane represented by formula (15) is shown below.

(R³²)ₚSi(OR³³)₄₋ₚ (15)

In formula (15), R³² represents a hydrogen atom, an alkyl group having 1 to 10 carbon atoms, an alkenyl group having 2 to 10 carbon atoms, or an aryl group having 6 to 16 carbon atoms; R³³ represents a hydrogen atom, an alkyl group having 1 to 6 carbon atoms, an acyl group having 2 to 6 carbon atoms, or an aryl group haying 6 to 16 carbon atoms; and p is an integer from 0 to 3. When p is two or more, the plurality of R³²s may each be the same or different. When p is two or less, the plurality of R³³s may each be the same or different.

Examples of the organosilane represented by formula (15) include: a tetrafunctional silane, such as tetramethoxysilane, tetraethoxysilane, tetraacetoxysilane, and tetraphenoxysilane; a trifunctional silane, such as methyltrimethoxysilane, methyltriethoxysilane, methyltriisopropoxysilane, methyltri-n-butoxysilane, ethyltrimethoxysilane, ethyltriethoxysilane, ethyltriisopropoxysilane, ethyltri-n-butoxysilane, n-propyltrimethoxysilane, n-propyltriethoxysilane, n-butyltrimethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, phenyltrimethoxysilane, phenyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxy-5-(p-hydroxyphenylcarbonyloxy)pentyltrimethoxysilane, trifluoromethyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, 3-trimethoxysilylpropylsuccinic acid, 1-naphthyltrimethoxysilane, 1-naphthyltriethoxysilane, 1-naphthyltri-n-propoxysilane, 2-naphthyltrimethoxysilane, 1-anthracenyltrimethoxysilane, 9-anthracenyltrimethoxysilane, 9-phenanthrenyltrimethoxysilane, 9-fluorenyltrimethoxysilane, 2-fluorenyltrimethoxysilane, 1-pyrenyltrimethoxysilane, 2-indenyltrimethoxysilane, and 5-acenaphthenyltrimethoxysilane; a bifunctional silane, such as dimethyldimethoxysilane, dimethyldiethoxysilane, dimethyldiacetoxysilane, di-n-butyldimethoxysilane, diphenyldimethoxysilane, (3-glycidoxypropyl)methyldimethoxysilane, (3-glycidoxypropyl)methyldiethoxysilane, di(1-naphthyl)dimethoxysilane, and di(1-naphthyl)diethoxysilane; a monofunctional silane, such as trimethylmethoxysilane, tri-n-butylethoxysilane, (3-glycidoxypropyl)dimethylmethoxysilane, and (3-glycidoxypropyl)dimethylethoxysilane; and a combination of two or more thereof.

The organosilane represented by formula (16) is shown below.

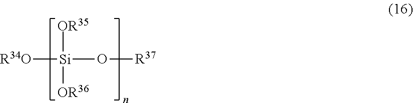

In formula (16), R³⁴ to R³⁷ each independently represent a hydrogen atom, an alkyl group having 1 to 6 carbon atoms, an acyl group having 2 to 6 carbon atoms or an aryl group having 6 to 16 carbon atoms, and n is in the range of 2 to 8. When n is two or more, the plurality of R³⁵s and R³⁶s may be the same or different.

Specific examples of the organosilane represented by formula (16) include: methyl silicate 51 (R³⁴ to R³⁷ are methyl groups and n is an average of 4) manufactured by Fuso Chemical Co., Ltd; M silicate 51 (R³⁴ to R³⁷ are methyl groups and n is an average of 3 to 5), silicate 40 (R³⁴ to R³⁷ are ethyl groups and n is an average of 4 to 6), and silicate 45 (R³⁴ to R³⁷ are ethyl groups and n is an average of 6 to 8) manufactured by Tama Chemicals Co., Ltd.; and methyl silicate 51 (R³⁴ to R³⁷ are methyl groups and n is an average of 4), methyl silicate 53A (R³⁴ to R³⁷ are methyl groups and n is an average of 7), and ethyl silicate 40 (R³⁴ to R³⁷ are ethyl groups and n is an average of 5) manufactured by Colcoat Co., Ltd. These may be used in combination of two or more of thereof.

The silicone resin (i) can be synthesized by the hydrolysis and partial condensation of the organosilanes represented by formula (15) and formula (16). Partial condensation results in a residual silanol group being present in the silicone resin (i). Hydrolysis and partial condensation can be carried out by, for example, a method in which a solvent, water, a catalyst, etc., are added as necessary to the organosilane mixture, which is then heated and stirred at a temperature of 50 to 150° C. for 0.5 to 100 hours. By-products of hydrolysis (alcohols, such as methanol) or by-products of condensation (water) may be evaporated off by distillation.

An acidic or basic catalyst is preferably used as the catalyst. Examples of the acidic catalyst include hydrochloric acid, nitric acid, sulfuric acid, hydrofluoric acid, phosphoric acid, acetic acid, trifluoroacetic acid, formic acid, a polycarboxylic acid or an anhydride thereof, and an ion exchange resin. Examples of the basic catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, an alkoxysilane having an amino group, and an ion exchange resin. After hydrolysis and partial condensation, the catalyst may be removed by washing with water, treating with an ion exchange resin, or a combination thereof as necessary. By removing the catalyst, the storage stability of the photosensitive resin composition can be improved.

The weight average molecular weight (Mw) of the silicone resin (i) is preferably 1,000 to 100,000, and more preferably 1,000 to 50,000. When the weight average molecular weight is 1,000 or more, the film formability can be improved, and when the weight average molecular weight is 100,000 or less, the alkali developability is favorable.

### (j) Cyclic Olefin Polymer

In one embodiment, the binder resin (A) includes a cyclic olefin polymer (j). The cyclic olefin polymer (j) is a homopolymer or copolymer of a cyclic olefin monomer having an alicyclic structure and an ethylenically unsaturated double bond. The cyclic olefin polymer (j) may have a structural unit derived from a monomer other than the cyclic olefin monomer.

Examples of the monomer constituting the cyclic olefin polymer (j) include a cyclic olefin monomer having a polar protic group, a cyclic olefin monomer having a polar aprotic group, a cyclic olefin monomer having no polar group, and a monomer other than the cyclic olefin. The monomer other than the cyclic olefin may have a polar protic group or a polar group other than the polar protic group, or may have no polar group.

Examples of the cyclic olefin monomer having a polar protic group include: a carboxy group-containing cyclic olefin, such as 5-hydroxycarbonylbicyclo[2.2.1]hept-2-ene, 5-methyl-5-hydroxycarbonylbicyclo[2.2.1]hept-2-ene, 5-carboxymethyl-5-hydroxycarbonylbicyclo[2.2.1]hept-2-ene, 5-exo-6-endo-dihydroxycarbonylbicyclo[2.2.1]hept-2-ene, 8-hydroxycarbonyltetracyclo[4.4.0.1^{2.5}.1^{7,10}]dodec-3-ene, 8-methyl-8-hydroxycarbonyltetracyclo[4.4.0.1^{2,5}.1^{7,10}]dodec-3-ene, and 8-exo-9-endo-dihydroxycarbonyltetracyclo[4.4.0.1^{2,5}.1^{7,10}]dodec-3-ene; a hydroxy group-containing cyclic olefin, such as 5-(4-hydroxyphenyl)bicyclo[2.2.1]hept-2-ene, 5-methyl-5-(4-hydroxyphenyl)bicyclo[2.2.1]hept-2-ene, 8-(4-hydroxyphenyl)tetracyclo[4.4.0.1^{2,5}.1^{7,10}]dodec-3-ene, and 8-methyl-8-(4-hydroxyphenyl)tetracyclo[4.4.0.1^{2,5}.1^{7,10}]dodec-3-ene; and a combination of two or more thereof.

Examples of the cyclic olefin monomer having a polar aprotic group include: a cyclic olefin having an ester group, such as 5-acetoxybicyclo[2.2.1]hept-2-ene, 5-methoxycarbonylbicyclo[2.2.1]hept-2-ene, 5-methyl-5-methoxycarbonylbicyclo[2.2.1]hept-2-ene, 8-acetoxytetracyclo[4.4.0.1^{2,5}.1^{7,10}]dodec-3-ene, 8-methoxycarbonyltetracyclo[4.4.0.1^{2,5}.1^{7,10}]dodec-3-ene, 8-ethoxycarbonyltetracyclo[4.4.0.1^{2,5}.1^{7,10}]dodec-3-ene, 8-n-propoxycarbonyltetracyclo[4.4.0.11^{2,5}.1^{7,10}]dodec-3-ene, 8-isopropoxycarbonyltetracyclo[4.4.0.1^{2,5}.1^{7,10}]dodec-3-ene, 8-n-butoxycarbonyltetracyclo[4.4.0.1^{2,5}.1^{7,10}]dodec-3-ene, 8-methyl-8-methoxycarbonyltetracyclo[4.4.0.1^{2,5}.1^{7,10}]dodec-3-ene, 8-methyl-8-ethoxycarbonyltetracyclo[4.4.0.1^{2,5}.1^{7,10}]dodec-3-ene, 8-methyl-8-n-propoxycarbonyltetracyclo[4.4.0.1^{2,5}.1^{7,10}]dodec-3-ene, 8-methyl-8-isopropoxycarbonyltetracyclo[4.4.0.1^{2,5}.1^{7,10}]dodec-3-ene, 8-methyl-8-n-butoxycarbonyltetracyclo[4.4.0.1^{2,5}.1^{7,10}]dodec-3-ene, 8-(2,2,2-trifluoroethoxycarbonyl)tetracyclo[4.4.0.1^{2,5}.1^{7,10}]dodec-3-ene, and 8-methyl-8-(2,2,2-trifluoroethoxycarbonyl)tetracyclo[4.4.0.1^{2,5}.1^{7,10}]dodec-3-ene; a cyclic olefin having an N-substituted imido group, such as N-phenyl(5-norbornene-2,3-dicarboximide) a cyclic olefin having a cyano group, such as 8-cyanotetracyclo[4.4.0.1^{2,5}.1^{7,10}]dodec-3-ene, 8-methyl-8-cyanotetracyclo[4.4.0.1^{2,5}.1^{7,10}]dodec-3-ene, and 5-cyanobicyclo[2.2.1]hept-2-ene; a cyclic olefin having a halogen atom, such as 8-chlorotetracyclo[4.4.0.1^{2,5}.1^{7,10}]dodec-3-ene, and 8-methyl-8-chlorotetracyclo[4.4.0.1^{2,5}.1^{7,10}]dodec-3-ene; and a combination of two or more thereof.

Examples of the cyclic olefin monomer having no polar group include bicyclo[2.2.1]hept-2-ene, 5-ethyl-bicyclo[2.2.1]hept-2-ene, 5-butyl-bicyclo[2.2.1]hept-2-ene, 5-ethylidene-bicyclo[2.2.1]hept-2-ene, 5-methylidene-bicyclo[2.2.1]hept-2-ene, 5-vinyl-bicyclo[2.2.1]hept-2-ene, tricyclo[4.3.0.1^{2,5}]deca-3,7-diene, tetracyclo[8.4.0.1^{11,14}.0^{3,7}]pentadeca-3,5,7,12,11-pentaene, tetracyclo[4.4.0.1^{2,5}.1^{7,10}]dec-3-ene, 8-methyl-tetracyclo[4.4.0.1^{2,5}.1^{7,10}]dodec-3-ene, 8-ethyl-tetracyclo[4.4.0.1^{2,5}.1^{7,10}]dodec-3-ene, 8-methylidene-tetracyclo[4.4.0.1^{2,5}.1^{7,10}]dodec-3-ene, 8-ethylidene-tetracyclo[4.4.0.1^{2,5}.1^{7,10}]dodec-3-ene, 8-vinyl-tetracyclo[4.4.0.1^{2,5}.1^{7,10}]dodec-3-ene, 8-propenyl-tetracyclo[4.4.0.1^{2,5}.1^{7,10}]dodec-3-ene, pentacyclo[6.5.1.1^{3,6}.0^{2,7}.0^{9,13}]pentadeca-3,10-diene, cyclopentene, cyclopentadiene, 1,4-methano-1.4.4a,5,10,10a-hexahydroanthracene, 8-phenyl-tetracyclo[4.4.0.1^{2,5}.1^{7,10}]dodec-3-ene, tetracyclo[9.2.1.0^{2,10}.0^{3,8}]tetradeca-3,5,7,12-tetraene, pentacyclo[7.4.0.1^{3,6}.1^{10,13}.0^{2,7}]pentadeca-4,11-diene, and pentacyclo[9.2.1.14,7.0^{2,10}.0^{3,8}]pentadeca-5,12-diene, and a combination of two or more thereof.

Specific examples of the monomer other than the cyclic olefin include: α-olefins having 2 to 20 carbon atoms, such as ethylene, propylene, 1-butene, 1-pentene, 1-hexene, 3-methyl-1-butene, 3-methyl-1-pentene, 3-ethyl-1-pentene, 4-methyl-1-pentene, 4-methyl-1-hexene, 4,4-dimethyl-1-hexene, 4,4-dimethyl-1-pentene, 4-ethyl-1-hexene, 3-ethyl-1-hexene, 1-octene, 1-decene, 1-dodecene, 1-tetradecene, 1-hexadecene, 1-octadecene, and 1-eicosene; linear olefins, such as non-conjugated dimes, including 1,4-hexadiene, 4-methyl-1,4-hexadiene, 5-methyl-1,4-hexadiene, and 1,7-octadiene; and a combination of two or more thereof.

The cyclic olefin polymer (j) can be synthesized by ring-opening polymerization or addition polymerization of the aforementioned monomers. As a polymerization catalyst, a metal complex, for example, a molybdenum, ruthenium or osmium complex or a combination of two or more thereof is preferably used. The cyclic olefin polymer may undergo hydrogenation treatment. A catalyst that is generally used for the hydrogenation of olefin compounds may be used as the hydrogenation catalyst. Examples of the catalyst include a Ziegler-type homogeneous catalyst, a precious metal complex catalyst, and a supported precious metal catalyst.

The weight average molecular weight (Mw) of the cyclic olefin polymer (j) is preferably 1,000 to 100,000, and more preferably 1,000 to 50,000. When the weight average molecular weight is 1,000 or more, the film formability can be improved, and when the weight average molecular weight is 100,000 or less, the alkali developability is favorable.

### (k) Cardo Resin

In one embodiment, the binder resin (A) includes a cardo resin (k). The cardo resin (k) has a cardo structure, namely, a skeleton structure in which a quaternary carbon atom constituting a cyclic structure is bonded to two other cyclic structures. Examples of the skeleton structure in which a quaternary carbon atom constituting a cyclic structure is bonded to two other cyclic structures include a fluorene skeleton, a bisphenol fluorene skeleton, a bisaminophenyl fluorene skeleton, a fluorene skeleton having an epoxy group, and a fluorene skeleton having an acrylic group. Examples of the cardo structure include a fluorene ring bonded to a benzene ring.

The cardo resin (k) can be synthesized by polymerizing a monomer having the cardo structure by reacting functional groups thereof with each other. Examples of the method for polymerizing the monomer having the cardo structure include ring-opening polymerization and addition polymerization. Examples of the monomer having the cardo structure include: a cardo structure-containing bisphenol compound, such as a bis(glycidyloxyphenyl)fluorene epoxy resin, a 9,9-bis(4-hydroxyphenyl)fluorene, and 9,9-bis(4-hydroxy-3-methylphenyl)fluorene; a 9,9-bis(cyanoalkyl)fluorene compound, such as 9,9-bis(cyanomethyl)fluorene; a 9,9-bis(aminoalkyl)fluorene compound, such as 9,9-bis(3-aminopropyl)fluorene; and a combination of two or more thereof. The cardo resin (k) may be a copolymer of the monomer having the cardo structure and an additional monomer that can be copolymerized therewith.

The weight average molecular weight (Mw) of the cardo resin (k) is preferably 1,000 to 100,000 and more preferably 1,000 to 50,000. When the weight average molecular weight is 1,000 or more, the film formability can be improved, and when the weight average molecular weight is 100,000 or less, the alkali developability is favorable.

In one embodiment, the binder resin (A) includes a phenolic resin, such as a phenolic novolak resin, a cresol novolak resin, a triphenylmethane phenolic resin, a phenolic aralkyl resin, a biphenylaralkylphenolic resin, a phenol-dicyclopentadiene copolymer resin, or a derivative thereof. When a phenolic resin is used as the binder resin (A), a preferable number average molecular weight is generally 100 to 50,000, more preferably 500 to 30,000, and still more preferably 800 to 10,000, although this depends on the resin structure. When the number average molecular weight is 100 or more, the rate of alkali development is suitable, and since the difference in dissolution rate between the exposed parts and the unexposed parts is sufficient, pattern resolution is favorable, and when the number average molecular weight is 50,000 or less, the alkali developability is favorable.

The binder resin (A) may be used alone or in combination of two or more thereof.

The content of the binder resin (A) in the photosensitive resin composition with respect to 100 parts by mass of the total of the binder resin (A), the radiation sensitive compound (B), and the dye (C) may be 5 to 60 parts by mass, preferably 10 to 55 parts by mass, and more preferably 10 to 50 parts by mass. When the content of the binder resin (A) is 5 part by mass or more with respect to 100 parts by mass of the total, the residual coating ratio, heat resistance and sensitivity are suitable. When the content of the binder resin (A) is 60 parts by mass or less with respect to 100 parts by mass of the total, the optical density (OD value) of a coating after curing may be a desired value or more, e.g., 1 or more per μm of coating thickness, and light shielding properties can be retained even after curing.

The binder resin (A) is preferably at least one selected from the resin components (a) to (k), more preferably at least one selected from the resin components (a) to (d), and still more preferably at least one selected from the resin components (c) and (d). In another preferred embodiment, the binder resin (A) is at least one selected from (a), (b), and (c).

When a plurality of the resin components (a) to (k) are included, any combination thereof is possible. Preferably at least two selected from the group consisting of the resin components (a) to (d), more preferably at least two selected from the group consisting of the resin components (a), (c), and (d), and still more preferably the resin components (c) and (d) are included.

The total amount of the at least one resin component selected from the group consisting of (a) to (d) in the binder resin (A) is preferably 0.5% by mass or more, more preferably 50% by mass or more, and still more preferably 88% by mass or more. When the total amount of the at least one resin component selected from the group consisting of (a) to (d) in the binder resin (A) is 0.5% by mass or more, the heat resistance of the resin composition is favorable.

Four types of the resin components (a) to (d) may be used in combination. When using the four types in combination, it is preferable that, in the binder resin (A), the proportion of the polyalkenylphenolic resin (a) be 5 to 50% by mass, the proportion of the hydroxypolystyrene resin derivative (b) be 5 to 30% by mass, the proportion of the aqueous alkaline solution-soluble resin having an epoxy group and a phenolic hydroxy group (c) be 10 to 80% by mass, and the aqueous alkaline solution-soluble copolymer of a polymerizable monomer having an alkali-soluble functional group and an additional polymerizable monomer (d) be 10 to 80% by mass.

### [Radiation Sensitive Compound (B)]

As the radiation sensitive compound (B), a photoacid generator, a photobase generator or a photopolymerization initiator may be used. The photoacid generator is a compound that generates an acid when exposed to radiation, such as visible light, ultraviolet light, γ rays, and electron beams. Since the photoacid generator increases the solubility in an aqueous alkaline solution of parts exposed to radiation, the photoacid generator can be used in positive tone photosensitive resin compositions in which the parts are made to be dissolved. The photobase generator is a compound that generates a base when exposed to radiation. Since the photobase generator decreases the solubility in an aqueous alkaline solution of parts exposed to radiation, the photobase generator can be used in negative tone photosensitive resin compositions in which the parts are made to be non-soluble. The photopolymerization initiator is a compound that generates a radical when exposed to radiation. When the photosensitive resin composition comprises a radical polymerizable functional group-containing binder or a radical polymerizable compound, radical polymerization of irradiated parts of the radical polymerizable functional groups of the binder resin or the radical polymerizable compound proceeds, and a polymerized product which is insoluble in an aqueous alkaline solution is formed in the parts. Thus, the photopolymerization initiator can be used in negative tone photosensitive resin compositions.

It is preferable from the viewpoint of achieving high sensitivity and high pattern resolution that the radiation sensitive compound (B) be a photoacid generator. As the photoacid generator, at least one selected from the group consisting of quinone diazide compounds, sulfonium, salts, phosphonium salts, diazonium salts, and iodonium salts may be used. In one embodiment, the photoacid generator is a compound or salt with high sensitivity to i-rays (365 nm).

It is preferable that as the photoacid generator, a quinone diazide compound be used. Examples of the quinone diazide compound include a polyhydroxy compound to which a sulfonic acid of a quinone diazide is bonded via an ester, a polyamino compound to which a sulfonic acid of a quinone diazide is bonded via a sulfonamide, and a polyhydroxy polyamino compound to which a sulfonic acid of a quinone diazide is bonded via an ester or sulfonamide. From the viewpoint of contrast between exposed and unexposed parts, it is preferable that at least 20 mol % of the total of the functional groups of the polyhydroxy compound or polyamino compound be substituted with a quinone diazide.

Examples of the polyhydroxy compound include Bis-Z, BisP-EZ, TekP-4HBPA, TrisP-HAP, TrisP-PA, TrisP-SA, TrisOCR-PA, BisOCHP-Z, BisP-MZ, BisP-PZ, BisP-IPZ, BisOCP-IPZ, BisP-CP, BisRS-2P, BisRS-3P, BisP-OCHP, methylenetris-FR-CR, BisRS-26X, DML-MBPC, DML-MBOC, DML-OCHP, DML-PCHP, DML-PC, DML-PTBP, DML-34X, DML-EP, DML-POP, dimethylol-BisOC-P, DML-PFP, DML-PSBP, DML-MTrisPC, TriML-P, TriML-35XL, TML-BP, TML-HQ, TML-pp-BPF, TML-BPA, TMOM-BP, HML-TPPHBA, and HML-TPHAP (trade names, Honshu Chemical industry Co., Ltd.), BIR-OC, BIP-PC, BIR-PC, BIR-PTBP, BIR-PCHP, BIP-BIOC-F, 4PC, BIR-BIPC-F, TEP-BIP-A, 46DMOC, 46DMOEP, and TM-BIP-A (trade names, Asahi Yukizai Corporation), 2,6-dimethoxymethyl-4-tert-butylphenol, 2,6-dimethoxymethyl-p-cresol, 2,6-diacetoxymethyl-p-cresol, naphthol, tetrahydroxybenzophenone, gallic acid methyl ester, bisphenol A, bisphenol E, methylene bisphenol, and BisP-AP (trade name, Honshu Chemical industry Co., Ltd,), but are not limited thereto.

Examples of the polyamino compound include 1,4-phenylenediamine, 1,3-phenylenediamine, 4,4′-diaminodiphenyl ether, 4,4′-diaminodiphenylmethane, 4,4′-diaminodiphenyl sulfone, and 4,4′-diaminodiphenyl sulfide, but are not limited thereto.

Examples of the polyhydroxy polyamino compound include 2,2-bis(3-amino-4-hydroxyphenyl)hexafluoropropane, and 3,3′-dihydroxybenzidine, but are not limited thereto.

The quinone diazide compound is preferably a 1,2-naphthoquinonediazido-4-sulfonic acid ester or a 1,2-naphthoquinonediazido-5-sulfonic acid ester of the polyhydroxy compound, and more preferably a 1,2-naphthoquinonediazido-4-sulfonic acid ester of the same.

The quinone diazide compound forms a carboxy group when exposed to ultraviolet light, etc., through the reaction illustrated in reaction formula 2 below. The formation of the carboxy group makes an exposed part (coating) soluble in an aqueous alkaline solution and generates alkali developability in the part.

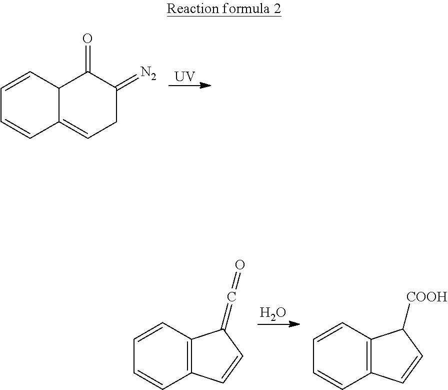

When the radiation sensitive compound (B) is a photoacid generator, the content of the photoacid generator in the photosensitive resin composition with respect to 100 parts by mass of the total of the binder resin (A), the radiation sensitive compound (B), and the dye (C) may be 5 to 50 parts by mass, preferably 10 to 45 parts by mass, and more preferably 15 to 40 parts by mass. When the content of the photoacid generator with respect to 100 parts by mass of the total is 5 part by mass or more, the alkali developability is favorable, and when the content is 50 parts by mass or less, the reduction of coating due to heat treatment at 300° C. or higher can be suppressed.

As the radiation sensitive compound (B), a photobase generator may be used. As the photobase generator, at least one selected from the group consisting of amide compounds and ammonium salts may be used. In one embodiment, the photobase generator is a compound or salt with high sensitivity to i-rays (365 nm).

Examples of the amide compound include 2-nitrophenylmethyl-4-methacryloyloxypiperidine-1-carboxylate, 9-anthrylmethyl-N,N-dimethyl carbamate, 1-(anthraquinone-2-yl)ethylimidazole carboxylate, and (E)-1-[3-(2-hydroxyphenyl)-2-propenoyl]piperidine. Examples of the ammonium salt include 1,2-diisopropyl-3-[bis(dimethylamino)methylene]guanidinium 2-(3-benzoylphenyl)propionate, (Z)-{[bis(dimethylamino)methylidene]amino}-N-cyclohexylamino)methanaminium tetrakis(3-fluorophenyl)borate, and 1,2-dicyclohexyl-4,4,5,5-tetramethylbiguanidinium n-butyltriphenylborate.

When the radiation sensitive compound (B) is a photobase generator, the content of the photobase generator in the photosensitive resin composition with respect to 100 parts by mass of the total of the binder resin (A), the radiation sensitive compound (B), and the dye (C) may be 0.1 to 25 parts by mass, preferably 0.5 to 20 parts by mass, and more preferably 1 to 15 parts by mass. When the content of the photobase generator with respect to 100 parts by mass of the total is 0.1 parts by mass or more, the alkali developability is favorable, and when the content is 20 parts by mass or less, the reduction of coating due to heat treatment at 300° C. or higher can be suppressed.

As the radiation sensitive compound (B), a photopolymerization initiator may be used. As the photopolymerization initiator, at least one selected from the group consisting of benzyl ketal compounds, α-hydroxy ketone compounds, α-amino ketone compounds, acyl phosphine oxide compounds, oxime ester compounds, acridine compounds, benzophenone compounds, acetophenone compounds, aromatic keto ester compounds and benzoic acid esters compounds can be used. In one embodiment, the photopolymerization initiator is a compound with high sensitivity to i-rays (365 nm). Since the sensitivity is high during exposure, the photopolymerization initiator is preferably an α-hydroxy ketone compound, an α-amino ketone compound, an acyl phosphine oxide compound, an oxime ester compound, an acridine compound or a benzophenone compound, and more preferably an α-amino ketone compound, an acyl phosphine oxide compound, or an oxime ester compound.

Examples of the benzyl ketal compound include 2,2-dimethoxy-1,2-diphenylethan-1-one. Examples of the α-hydroxy ketone compound include 1-(4-isopropylphenyl)-2-hydroxy-2-methylpropan-1-one, 2-hydroxy-2-methyl-1-phenylpropan-1-one, 1-hydroxycyclohexyl phenyl ketone, 1-[4-(2-hydroxyethoxy)phenyl]-2-hydroxy-2-methylpropan-1-one, and 2-hydroxy-1-[4-[4-(2-hydroxy-2-methylpropionyl)benzyl]phenyl]-2-methylpropan-1-one. Examples of the α-amino ketone compound include 2-dimethylamino-2-methyl-1-phenylpropan-1-one, 2-diethylamino-2-methyl-1-phenylpropan-1-one, 2-methyl-2-morpholino-1-phenylpropan-1-one, 2-dimethylamino-2-methyl-1-(4-methylphenyl)propan-1-one, 2-dimethylamino-1-(4-ethylphenyl)-2-methylpropan-1-one, 2-dimethylamino-1-(4-isopropylphenyl)-2-methylpropan-1-one, 1-(4-butylphenyl)-2-dimethylamino-2-methylpropan-1-one, 2-dimethylamino-1-(4-methoxyphenyl)-2-methylpropan-1-one, 2-dimethylamino-2-methyl-1-(4-methylthiophenyl)propan-1-one, 2-methyl-1-(4-methylthiophenyl)-2-morpholinopropan-1-one, 2-benzyl-2-dimethylamino-1-(4-morpholinophenyl)-butan-1-one, 2-benzyl-2-dimethylamino-1-(4-dimethylaminophenyl)-butan-1-one, and 2-dimethylamino-2-[(4-methylphenyl)methyl]-1-[4-(4-morpholinyl)phenyl]-1-butanone. Examples of the acyl phosphine oxide compound include 2,4,6-trimethylbenzoyl-diphenylphosphine oxide, bis(2,4,6-trimethylbenzoyl)-phenylphosphine oxide, and bis(2,6-dimethoxybenzoyl)-(2,4,4-trimethylpentyl)phosphine oxide. Examples of the oxime ester compound include 1-phenylpropane-1,2-dione-2-(O-ethoxycarbonyl)oxime, 1-phenylbutane-1,2-dione-2-(O-methoxycarbonyl)oxime, 1,3-diphenylpropane-1,2,3-trione-2-(O-ethoxycarbonyl)oxime, 1-[4-(phenylthio)phenyl]octane-1,2-dione-2-(O-benzoyl)oxime, 1-[4-[4-(carboxyphenyl)thio]phenyl]propane-1,2-dione-2-(O-acetyl)oxime, 1-[9-ethyl-6-(2-methylbenzoyl)-9H-carbazol-3-yl]ethanone-1-(O-acetyl)oxime, and 1-[9-ethyl-6-[2-methyl-4-[1-(2,2-dimethyl-1,3-dioxolan-4-yl)methyloxy]benzoyl]-9H-carbazol-3-yl]ethanone-1-(O-acetyl)oxime. Examples of the acridine compound include 1,7-bis(acridin-9-yl)-n-heptane. Examples of the benzophenone compound include benzophenone, 4,4′-bis(dimethylamino)benzophenone, 4,4′-bis(diethylamino)benzophenone, 4-phenylbenzophenone, 4,4-dichlorobenzophenone, 4-hydroxybenzophenone, alkylated benzophenones, 3,3′,4,4′-tetrakis(tert-butylperoxycarbonyl)benzophenone, 4-methylbenzophenone, dibenzyl ketone, and fluorenone. Examples of the acetophenone compound include 2,2-diethoxyacetophenone, 2,3-diethoxyacetophenone, 4-tert-butyldichloroacetophenone, benzalacetophenone, and 4-azidobenzalacetophenone. Examples of the aromatic keto ester compound include methyl 2-phenyl-2-oxyacetate. Examples of the benzoic acid ester compound include ethyl 4-dimethylaminobenzoate, (2-ethyl)hexyl 4-dimethylaminobenzoate, ethyl 4-diethylaminobenzoate, and methyl 2-benzoylbenzoate.

When the binder resin (A) has a cationic polymerizable group, such as an epoxy group, it is possible to use a photo-cationic polymerization initiator that generates a cation species or Lewis acid upon exposure to light. Examples of the photo-cationic polymerization initiator include an onium salt composed of a cationic part and an anionic part, wherein the cationic part is a sulfonium, such as triphenylsulfonium and diphenyl-4-(phenylthio)phenylsulfonium; an iodonium, such as diphenyliodonium and bis(dodecylphenyl)iodonium; a diazonium, such as phenyldiazonium; a pyridinium, such as 1-benzyl-2-cyanopyridium and 1-(naphthylmethyl)-2-cyanopyridinium; or an Fe cation, such as (2,4-cyclopentadien-1-yl)[(1-methylethyl)benzene]-Fe, and the anionic part is BF₄⁻, PF₆⁻, SbF₆⁻, or [BX₄]⁻ (where X is a phenyl group substituted with at least two fluorine atoms or a trifluoromethyl group).

When the radiation sensitive compound (B) is a photopolymerization initiator, the content of the photopolymerization initiator in the photosensitive resin composition with respect to 100 parts by mass of the total of the binder resin (A), the radiation sensitive compound (B), and the dye (C) may be 0.1 to 25 parts by mass, preferably 0.5 to 20 parts by mass, and more preferably 1 to 15 parts by mass. When the content of the photopolymerization initiator with respect to 100 parts by mass of the total is 0.1 parts by mass or more, the alkali developability is favorable, and when the content is 20 parts by mass or less, the reduction of coating due to heat treatment at 300° C. or higher can be suppressed.

When the radiation sensitive compound (B) is a photopolymerization initiator, the photosensitive resin composition may further contain a radical polymerizable compound. As the radical polymerizable compound, a resin or compound having a plurality of ethylenically unsaturated groups can form crosslinking in a coating to increase the hardness thereof.

From the viewpoint of reactivity during exposure, and hardness and heat resistance of a coating, the radical polymerizable compound is preferably a compound having a plurality of (meth)acrylic groups. Examples of such a compound include diethylene glycol di(meth)acrylate, triethylene glycol di(meth)acrylate, tetraethylene glycol di(meth)acrylate, propylene glycol di(meth)acrylate, trimethylolpropane di(meth)acrylate, trimethylolpropane tri(meth)acrylate, ethoxylated trimethylolpropane di(meth)acrylate, ethoxylated trimethylolpropane tri(meth)acrylate, ditrimethylolpropane tri(meth)acrylate, ditrimethylolpropane tetra(meth)acrylate, 1,3-butanediol di(meth)acrylate, neopentyl glycol di(meth)acrylate, 1,4-butanediol di(meth)acrylate, 1,6-hexanediol di(meth)acrylate, 1,9-nonanediol di(meth)acrylate, 1,10-decanediol di(meth)acrylate, dimethylol-tricyclodecane di(meth)acrylate, ethoxylated glycerin tri(meth)acrylate, pentaerythritol tri(meth)acrylate, pentaerythritol tetra(meth)acrylate, ethoxylated pentaerythritol tri(meth)acrylate, ethoxylated pentaerythritol tetra(meth)acrylate, dipentaerythritol penta(meth)acrylate, dipentaerythritol hexa(meth)acrylate, tripentaerythritol hepta(meth)acrylate, tripentaerythritol octa(meth)acrylate, tetrapentaerythritol nona(meth)acrylate, tetrapentaerythritol deca(meth)acrylate, pentapentaerythritol undeca(meth)acrylate, pentapentaerythritol dodeca(meth)acrylate, ethoxylated bisphenol A di(meth)acrylate, 2,2-bis[4-(3-(meth)acryloxy-2-hydroxypropoxy)phenyl]propane, 1,3,5-tris((meth)acryloxyethyl)isocyanuric acid, 1,3-bis((meth)acryloxyethyl)isocyanuric acid, 9,9-bis[4-(2-(meth)acryloxyethoxy)phenyl]fluorene, 9,9-bis[4-(3-(meth)acryloxypropoxy)phenyl]fluorene, and 9,9-bis(4-(meth)acryloxyphenyl)fluorene, and an acid modified product, ethylene oxide modified product or propylene oxide modified product thereof.

The content of the radical polymerizable compound in the photosensitive resin composition with respect to 100 parts by mass of the binder resin (A) may be 15 to 65 parts by mass, preferably 20 to 60 parts by mass, and more preferably 25 to 50 parts by mass. When the content of the radical polymerizable compound is within the aforementioned ranges, the alkali developability is favorable and the heat resistance of a cured coating can be improved.

The dye (C) comprises a black dye (C 1) and a dye (C2) other than (C1). The dye (C2) has the absorption maximum at a wavelength from 480 to 550 nm in the wavelength range of 300 to 800 nm, and Abs2/Abs1 is 0.1 to 1.0 when the absorbance at the wavelength of the absorption maximum of the dye (C2) is taken as Abs1 and the average absorbance over the range of 560 to 600 nm wavelength is taken as Abs2. By combining the black dye (C1) and the dye (C2) as the dye, the content of the black dye (C1) can be reduced with keeping the light shielding properties of the photosensitive resin composition, so that the pattern formability of the photosensitive resin composition can be improved and the sensitivity can be enhanced. The photosensitive resin composition containing the dye, as compared to a photosensitive resin composition containing a pigment, leaves less colorant residue during development and can form high definition patterns in a coating. By forming black barrier ribs or a black insulating film in an organic EL element using the photosensitive resin composition containing a combination of the black dye (C1) and the dye (C2) as the dye, the visibility of a display device, such as an organic EL display, can be improved.

The types and contents of the black dye (C1) and the dye (C2) can be selected and determined so that the optical density (OD value) of a cured coating of the photosensitive resin composition is equal to or higher than a desired value, e.g., 1 or more per μm of coating thickness. Each of the black dye (C1) and the dye (C2) may be used alone or in combination of two or more thereof.

The black dye (C1) is not particularly limited, and examples thereof include a dye defined by the color index (C.I.) as solvent black 7 to 47. The black dye is preferably one defined by the C.I. as solvent black 27 to 47 and more preferably one defined by the C.I. as solvent black 27, 29 or 34. By using at least one black dye of the dyes defined by the C.I. as solvent black 7 to 47, the light shielding properties of a coating of the photosensitive resin composition after curing can be more effectively maintained.

Specific examples of the black dye (CI) include VALIFAST (trademark) BLACK 3804 (a black dye defined by the C.I. as solvent black 34, manufactured by Orient Chemical Industries Co., Ltd.), VALIFAST (trademark) BLACK 3830 (a black dye defined by the C.I. as solvent black 27, manufactured by Orient Chemical Industries Co., Ltd.), VALIFAST (trademark) BLACK 3810 (a black dye defined by the C.I. as solvent black 29, manufactured by Orient Chemical Industries Co., Ltd.), VALIFAST (trademark) BLACK 3820 (a black dye defined by the C.I. as solvent black 27, manufactured by Orient Chemical Industries Co., Ltd.), NUBIAN (trademark) BLACK TN-870 (a black dye defined by the C.I. as solvent black 7, manufactured by Orient Chemical Industries Co., Ltd.).

The dye (C2) is a dye other than the black dye (C1) and has the absorption maximum at a wavelength from 480 to 550 nm in the wavelength range of 300 to 800 nm. The absorbance of the black dye (C1) is generally relatively small in the range of 450 to 550 nm wavelength. By using the dye (C2) having the absorption maximum at a wavelength from 480 to 550 nm to complement the low absorbance of the black dye (C1) in the above wavelength region, the content of the black dye (C1) can be reduced with keeping the light shielding properties of the photosensitive resin composition, and the improvement of the pattern formability and the high sensitivity of the photosensitive resin composition can be effectively achieved. In one embodiment, the dye (C2) is preferably one having the absorption maximum at a wavelength from 500 to 550 nm in the wavelength range of 300 to 800 nm, and more preferably one having the absorption maximum at a wavelength from 500 to 540 nm.

In addition, the dye (C2) has Abs2/Abs1 of 0.1 to 1.0 when the absorbance at the wavelength of the absorption maximum is taken as Abs1 and the average absorbance over the range of 560 to 600 nm wavelength is taken as Abs2. By using the dye (C2), even when the ratio of the black dye (C1) is relatively lowered and the ratio of the dye (C2) is relatively increased, it is possible to effectively achieve the improvement in pattern formability and the high sensitivity of the photosensitive resin composition while suppressing a reduction in absorbance over the range of 560 to 600 nm wavelength due to reduction of the black dye (C1). In one embodiment, the dye (C2) preferably has Abs2/Abs1 of 0.2 to 0.8, more preferably 0.3 to 0.6. The absorbance of the dye (C2) is determined by measuring an absorption spectrum in the wavelength range of 300 to 800 nm in a spectrophotometer (trade name V670, manufactured by JASCO Corporation) in increments of 1 nm at 23° C. using a solution obtained by diluting the dye (C2) with γ-butyrolactone so as to be 10 ppm (on a mass basis). The average absorbance is a number average value of absorbance measured in increments of 1 nm in a predetermined wavelength range.

As the dye (C2), for example, those generally classified as red dyes may be used, but dyes other than red dyes may be used.

When the absorbance at the wavelength of the absorption maximum of the dye (C2) in the wavelength range of 300 to 800 nm is 100, the absorbance at 365 nm wavelength of the dye (C2) is preferably 0 to 80, more preferably from 30 to 75, and still more preferably from 50 to 70. When the absorbance at 365 nm wavelength of the dye (C2) is within the above range, the sensitivity of the photosensitive resin composition, particularly the sensitivity to the i-rays, can be increased.

The dye (C2) is preferably a red dye, and specific examples thereof include VALIFAST (trademark) RED 3312 (a red dye defined by the C.I. as solvent red 122, manufactured by Orient Chemical Industries Co., Ltd.), VALIFAST (trademark) RED 3311 (a red dye defined by the C.I. as solvent red 8, manufactured by Orient Chemical Industries Co., Ltd.).

The dye (C) may include other dyes (C3) other than the black dye (C1) and the dye (C2), as long as the effect of the invention is not impaired. Specific examples of the other dyes (C1) include an azo dye, a benzoquinone dye, a naphthoquinone dye, an anthraquinone dye, a cyanine dye, a squarylium dye, a croconium dye, a merocyanine dye, a stilbene dye, a diphenylmethane dye, a triphenylmethane dye, a flouran dye, a spiropyran dye, a phthalocyanine dye, an indigo dye, a fulgide dye, a nickel complex dye, and an azulene dye. Specific examples include: VALIFAST (trademark) ORANGE 3209 (an orange dye defined by the C.I. as solvent orange 62, manufactured by Orient Chemical Industries Co., Ltd.), VALIFAST (trademark) BROWN 3405 (a mixture of an dye defined by the C.I. as solvent yellow 82 and other dyes, manufactured by Orient Chemical industries Co., Ltd.), VALIFAST (trademark) BLUE 2602 (a blue dye defined by the C.I. as solvent blue 44, manufactured by Orient Chemical Industry Co., Ltd.).

The content of the dye (C) in the photosensitive resin composition with respect to 100 parts by mass of the total of the binder resin (A), the radiation sensitive compound (B), and the dye (C) is preferably from 15 to 50 parts by mass, more preferably from 20 to 45 parts by mass, and still more preferably from 25 to 40 parts by mass. When the content of the dye (C) is 15 parts by mass or more with respect to 100 parts by mass of the total, the light shielding properties of a coating after curing can be maintained. When the content of the dye (C) is 50 parts by mass or less with respect to 100 parts by mass of the total, the residual film ratio, heat resistance, sensitivity, etc., are suitable.

The content of the black dye (CI) in the photosensitive resin composition is preferably from 50 to 95% by mass, more preferably from 60 to 90% by mass, and still more preferably from 70 to 85% by mass, with respect to the total mass of the dye (C). By setting the content of the black dye (C1) in the photosensitive resin composition to 50% by mass or more with respect to the total mass of the dye (C), the chroma and lightness of a cured coating can be reduced to such an extent that an observer can visually recognize the cured coating as black, and by setting the content to 95% by mass or less, it is possible to effectively achieve the improvement in pattern formability and the high sensitivity of the photosensitive resin composition.

The content of the dye (C2) in the photosensitive resin composition is preferably from 5 to 35% by mass, more preferably from 11 to 33% by mass, and still more preferably from 15 to 25% by mass, with respect to the total mass of the dye (C). By selling the content of the dye (C2) in the photosensitive resin composition to 5% by mass or more with respect to the total mass of the dye (C), it is possible to effectively achieve the improvement in pattern formability and the high sensitivity of the photosensitive resin composition, and by setting the content to 35% by mass or less, the chroma and lightness of a cured coating can be reduced to such an extent that an is observer can visually recognize the cured coating as black.

### [Optional Component (D)]

The photosensitive resin composition may include, as an optional component, a dissolution accelerator, a thermosetting agent, a surfactant, a colorant other than the dye (C), etc. The optional component (D) is defined as any component that does not correspond to any of (A) to (C).

The photosensitive resin composition may contain a dissolution accelerator, for example, in order to enhance the solubility of an alkali-soluble part during development. As the dissolution accelerator, a low molecular weight compound having an alkali-soluble functional group is used. Among them, a compound having at least one group selected from a carboxy group and a phenolic hydroxy group is preferable. The low molecular weight compound having an alkali-soluble functional group may be used alone or in combination of two or more thereof.

Examples of the low molecular weight compound having a carboxy group include: aliphatic monocarboxylic acids, such as formic acid, acetic acid, propionic acid, butyric acid, valeric acid, pivalic acid, caproic acid, diethylacetic acid, enanthic acid, and caprylic acid; aliphatic dicarboxylic acids, such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid, and citraconic acid; aliphatic tricarboxylic acids, such as tricarballylic acid, aconitic acid, and camphoronic acid; aromatic monocarboxylic acids, such as benzoic acid, toluic acid, cumic acid, hemimellitic acid, and mesitylenic acid; aromatic polycarboxylic acids, such as phthalic acid, isophthalic acid, terephthalic acid, trimellitic acid, trimesic acid, mellophanic acid, and pyromellitic acid; aromatic hydroxycarboxylic acids, such as dihydroxybenzoic acid, trihydroxybenzoic acid, and gallic acid; and other carboxylic acids, such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid, and umbellic acid.

Examples of the low molecular weight compound having a phenolic hydroxy group include catechol, resorcinol, hydroquinone, propyl gallate, dihydroxynaphthalene, leucoquinizarin, 1,2,4-benzenetriol, anthracenetriol, pyrogallol, phloroglucinol, tetrahydroxybenzophenone, phenolphthalein, phenolphthalin, tris(4-hydroxyphenyl)methane, 1,1,1-tris(4-hydroxyphenyl)ethane, and α,α,α′-tris(4-hydroxyphenyl)-1-ethyl-4-isopropylbenzene.

The content of the dissolution accelerator with respect to 100 parts by mass of the total of the binder resin (A), the radiation sensitive compound (B), and the dye (C) may be 0.1 to 20 parts by mass, preferably 1 to 15 parts by mass, and more preferably 3 to 12 parts by mass. When the content of the dissolution accelerator with respect to 100 parts by mass of the total is 0.1 parts by mass or more, dissolution of the binder resin (A) can be effectively accelerated, and when the content is 20 parts by mass or less, excessive dissolution of the binder resin (A) can be suppressed to improve pattern formability, surface quality, etc., of a coating.

A thermal radical generator may be used as the thermosetting agent. Examples of a preferred thermal radical generator include organic peroxides, in particular, organic peroxides with a 10 hour half-life temperature of 100 to 170° C., such as dicumyl peroxide, 2,5-dimethyl-2,5-di(tert-butylperoxy)hexane, tert-butylcumyl peroxide, di-tert-butyl peroxide, 1,1,3,3-tetramethylbutyl hydroperoxide, and cumene hydroperoxide.

The content of the thermosetting agent with respect to 100 parts by mass of the total of the binder resin (A), the radiation sensitive compound (B), the dye (C), and other solid components (excluding the thermosetting agent) is preferably 5 parts by mass or less, more preferably 4 parts by mass or less, and still more preferably 3 parts by mass or less.

The photosensitive resin composition may include a surfactant, in order to, for example, improve coatability, smoothness of a coating, or developability of a coating. Examples of the surfactant include: polyoxyethylene alkyl ethers, such as polyoxyethylene lauryl ether, polyoxyethylene stearyl ether, and polyoxyethylene oleyl ether; polyoxyethylene aryl ethers, such as polyoxyethylene octyl phenyl ether, and polyoxyethylene nonyl phenyl ether; nonionic surfactants, such as polyoxyethylene dialkyl esters, including polyoxyethylene dilaurate, and polyoxyethylene distearate; fluorosurfactants, such as Megaface (trademark) F-251, Megaface (trademark) F-281, Megaface (trademark) F-430, Megaface (trademark) F-444, Megaface (trademark) R-40, Megaface (trademark) F-553, Megaface (trademark) F-554, Megaface (trademark) F-555, Megaface (trademark) F-556, Megaface (trademark) F-557, Megaface (trademark) F-558, Megaface (trademark) F-559 (trade names, DIC Corporation), Surflon (trademark) S-242, Surflon (trademark) S-243, Surflon (trademark) S-386, Surflon (trademark) S-420, and Surflon (trademark) S-611 (trade names, ACG Seimi Chemical Co., Ltd.); and organosiloxane polymers KP323, KP326, and KP341 (trade names, Shin-Etsu Chemical Co., Ltd.). These may be used alone or in combination of two or more thereof.

The content of the surfactant with respect to 100 parts by mass of the total of the binder resin (A), the radiation sensitive compound (B), the dye (C), and other solid components (excluding the surfactant) is preferably 2 parts by mass or less, more preferably 1 part by mass or less, and still more preferably 0.5 parts by mass or less.

The photosensitive resin composition may include a second colorant other than the dye (C). Examples of the second colorant include an organic pigment, and an inorganic pigment, and the second colorant may be used according to the intended purpose. The second colorant may be used in an amount that does not impair the effect of the invention.

Examples of the pigment include: black pigments such as carbon black, carbon nanotubes, acetylene black, graphite, iron black, aniline black, titanium black, a perylene pigment, and a lactam pigment; C.I. pigment yellow 20, 24, 86, 93, 109, 110, 117, 125, 137, 138, 147, 148, 153, 154, and 166; C.I. pigment orange 36, 43, 51, 55, 59, and 61; C.I. pigment red 9, 97, 122, 123, 149, 168, 177, 180, 192, 215, 216, 217, 220, 223, 224, 226, 227, 228, and 240; C.I. pigment violet 19, 23, 29, 30, 37, 40, and 50; C.I. pigment blue 15, 15:1, 15:4, 22, 60, and 64; C.I. pigment green 7; and C.I. pigment brown 23, 25, and 26.

### [Solvent (E)]

The photosensitive resin composition may be dissolved in a solvent and used as a solution (note that when a black pigment is included, the pigment is in suspension). In the present disclosure, a photosensitive resin composition containing a solvent (E) and having a viscosity suitable for use is also referred to as a coating composition. For example, by mixing specific amounts of the radiation sensitive compound (B), the dye (C), and an optional component (D), such as a dissolution accelerator, a thermosetting agent or a surfactant, as necessary, with a solution obtained by dissolving the binder resin (A) in the solvent (E), the photosensitive resin composition may be prepared in solution. The photosensitive resin composition may be adjusted to have a viscosity suitable for the coating method used by changing the amount of solvent.

Examples of the solvent include: glycol ethers, such as ethylene glycol monomethyl ether, ethylene glycol dimethyl ether, ethylene glycol methyl ethyl ether, and ethylene glycol monoethyl ether; ethylene glycol alkyl ether acetates, such as methyl cellosolve acetate, and ethyl cellosolve acetate; diethylene glycol compounds, such as diethylene glycol monomethyl ether, diethylene glycol diethyl ether, diethylene glycol dimethyl ether, diethylene glycol ethyl methyl ether, diethylene glycol monoethyl ether, and diethylene glycol monobutyl ether; propylene glycol alkyl ether acetate compounds, such as propylene glycol monomethyl ether acetate and propylene glycol monoethyl ether acetate; aromatic hydrocarbons, such as toluene and xylene; ketones, such as methyl ethyl ketone, methyl amyl ketone, cyclohexanone, 4-hydroxy-4-methyl-2-pentanone, and cyclohexanone; esters, such as ethyl 2-hydroxypropionate, methyl 2-hydroxy-2-methylpropionate, ethyl 2-hydroxy-2-methylpropionate, ethyl ethoxyacetate, ethyl hydroxyacetate, methyl 2-hydroxy-2-methylbutanoate, methyl 3-methoxypropionate, ethyl 3-methoxypropionate, methyl 3-ethoxypropionate, ethyl 3-ethoxypropionate, ethyl acetate, butyl acetate, methyl lactate, ethyl lactate, and γ-butyrolactone; and amide compounds, such as N-methyl-2-pyrrolidone N,N-dimethylformamide, and N,N-dimethylacetamide. These solvents may be used alone or in combination of two or more thereof.

The photosensitive resin composition may be prepared by dissolving or dispersing the binder resin (A), the radiation sensitive compound (B), the dye (C), and if necessary, the optional component (D), in the solvent (E) and mixing them. Depending on the intended use, the solid concentration of the photosensitive resin composition may be suitably determined. For example, the solid concentration of the photosensitive resin composition may be 1 to 60% by mass, 3 to 50% by mass, or 5 to 40% by mass.

A publicly-known method may be used for a dispersion mixing method when a pigment is used as the optional component (D). For example, a ball type mixer, such as a ball mill, a sand mill, a bead mill, a paint shaker, and a rocking mill, a blade type mixer, such as a kneader, a paddle mixer, a planetary mixer, and a Henschel mixer, and a roll type mixer, such as a three-roll mixer, may be used, as well as a mortar machine, a colloid mill, ultrasonic waves, a homogenizer, and a rotation and revolution mixer. From the viewpoint of dispersion efficiency and fine dispersing, a bead mill is preferably used.

The prepared photosensitive resin composition is usually preferably filtered prior to use. Examples of the filtration means include a millipore filter having a pore diameter of 0.05 to 1.0 μm.

The photosensitive resin composition thus prepared is excellent in long term storage stability.

In one embodiment, Abs4/Abs3 is 0.8 to 1.6 when the average absorbance over the range of 450 to 545 nm wavelength is taken as Abs3 and the average absorbance over the range of 550 to 650 nm wavelength is taken as Abs4 in the absorbance curve of the photosensitive resin composition. Abs4/Abs3 is preferably 0.9 to 1.5, and more preferably 1.0 to 1.4. When Abs4/Abs3 is 0.8 or more, the OD value is within a preferable range, and the light shielding properties of a cured coating is improved. When Abs4/Abs3 is 1.6 or less, the alkali solubility of exposed parts is improved. The absorbance curve of the photosensitive resin composition is determined by measuring an absorption spectrum in the wavelength range of 300 to 800 nm in a spectrophotometer (trade name V670, manufactured by JASCO Corporation) in increments of 1 nm at 23° C. using a solution obtained by diluting the photosensitive resin composition with γ-butyrolactone so as to be 12 ppm (on a mass basis). The average absorbance is a number average value of absorbance measured in increments of 1 nm in a predetermined wavelength range.

When the photosensitive resin composition is used in radiation lithography, the photosensitive resin composition is first dissolved or dispersed in a solvent to prepare a coating composition. Next, the coating composition is applied to the surface of a substrate, and the solvent is removed by means of heating, etc., to form a coating. There is no particular limitation on the method for applying the coating composition on the surface of the substrate, and for example, a spray method, a roll coating method, a slit method, or a spin coating method may be used.

After applying the coating composition to the surface of the substrate, the solvent is typically removed by heating, etc., to form a coating (pre-baking). Although the heating conditions vary depending on the type of each component, the blending ratio, etc., the coating can be usually obtained by heat treatment at 70 to 130° C., for example, for 30 seconds to 20 minutes on a hot plate, or for 1 to 60 minutes in an oven.

Next, the prebaked coating is irradiated with radiation (e.g., visible light, ultraviolet, far-ultraviolet, X-rays, electron beams, gamma rays, synchrotron radiation, etc.) through a photomask having a predetermined pattern (exposure step). When the quinone diazide compound is used as the radiation sensitive compound, preferable radiation is ultraviolet to visible light having a wavelength of 250 to 450 nm. In one embodiment, the radiation is g-, h- and i-rays. In another embodiment, the radiation is i-rays.

After the exposure step, the coating is developed by bringing the coating into contact with a developer, and the exposed parts are removed to form a pattern in the coating (developing step). The developer used may be an aqueous solution of an alkali compound, for example: inorganic alkalis, such as sodium hydroxide, potassium hydroxide, sodium carbonate, sodium silicate, sodium metasilicate, and ammonia water; primary amines, such as ethylamine and n-propylamine; secondary amines, such as diethyl amine and di-n-propylamine; tertiary amines, such as triethylamine and methyldiethylamine; alcohol amines, such as dimethylethanolamine and triethanolamine; quaternary ammonium salts, such as tetramethylammonium hydroxide, tetraethylammonium hydroxide, and choline; and cyclic amines, such as pyrrole, piperidine, 1,8-diazabicyclo[5.4.0]-7-undecene, and 1,5-diazabicyclo[4.3.0]-5-nonane. An aqueous solution obtained by adding a water-soluble organic solvent, such as methanol and ethanol, a surfactant, etc., to an aqueous alkali solution in appropriate amounts may be used as the developer. The developing time is typically between 30 and 180 seconds. The developing method may be any of a liquid filling method, a shower method, and a dipping method. After the development, a pattern can be formed in the coating by cleaning with running water for 30 to 90 seconds to remove unnecessary parts, and air-drying with compressed air or compressed nitrogen.

Then, a cured coating can be obtained by subjecting the patterned coating to heat treatment using a heating device, such as a hot plate or an oven, for example, at 100 to 350° C. for 20 to 200 minutes (post-baking, heat treatment step). During the heat treatment, the temperature may be maintained constant, continuously increased, or increased in a stepwise manner.

In one embodiment, the optical density (OD value) of a cured coating of the photosensitive resin composition is 1 or more per μm of coating thickness. The optical density (OD value) of a cured coating of the photosensitive resin composition is preferably 1.005 or more, and more preferably 1.01 or more. When the OD value of a cured coaling is 1 or more per μm of coating thickness, high light shielding properties can be achieved. In the present disclosure, the optical density (OD value) of a cured coating of the photosensitive resin composition is a value when the coating of the photosensitive resin composition is cured by heating at 120° C. under an atmospheric atmosphere for 80 seconds, and then at 250° C. under a nitrogen gas atmosphere for 60 minutes.

One embodiment is a method for producing an organic EL element barrier rib or an organic EL element insulating film, comprising: preparing a coating composition by dissolving or dispersing a photosensitive resin composition in a solvent; applying the coating composition to a substrate to form a coating; drying the coating by removing the solvent contained in the coating; irradiating the dried coating with radiation through a photomask thereby exposing the coating; developing the exposed coating by bringing the coating into contact with a developer to form a pattern in the coating; and heat treating the patterned coating at a temperature of 100° C. to 350° C. to form the organic EL element harrier rib or the organic EL element insulating film.

One embodiment is an organic EL element barrier rib comprising a cured product of the photosensitive resin composition.

One embodiment is an organic EL element insulating film comprising a cured product of the photosensitive resin composition.

One embodiment is an organic EL element comprising a cured product of the photosensitive resin composition.

### EXAMPLES

Hereinafter, the present invention will be specifically described based on Examples and Comparative Examples, but the present invention is not limited to the Examples.

The weight average molecular weight and the number average molecular weight of the binder resin (A) were calculated using a calibration curve prepared using a standard substance of polystyrene under the following measurement conditions.

Apparatus name: Shodex (trademark) GPC-101

Column: Shodex (trademark) LF-804

Mobile phase: tetrahydrofuran

Flow rate: 1.0 mL/min

Detector: Shodex (trademark) RI-71

Temperature: 40° C.

### (1) Synthesis of Binder Resin (A)

### Production Example 1

### Production of an Aqueous Alkaline Solution-Soluble Resin Having an Epoxy Group and a Phenolic Hydroxy Group (c) (First Resin)

In a 300 mL 3-neck flask, 75.2 g of γ-butyrolactone (manufactured by Mitsubishi Chemical Corporation) as a solvent, and 17.8 g of EPICLON (trademark) N-695 (cresol novolak epoxy resin, manufactured by DIC Corporation, epoxy equivalent: 214) as a compound having at least two epoxy groups per molecule were added, and dissolved under a nitrogen gas atmosphere at 60° C. 20.1 g (0.65 equivalents with respect to one equivalent of epoxy groups) of 3,5-dihydroxybenzoic acid (manufactured by Fujifilm Wako Pure Chemical Corporation) as a hydroxybenzoic acid compound, and 0.166 g (0.660 mmol) of triphenylphosphine (manufactured by Tokyo Chemical Industry Co., Ltd.) as a reaction catalyst were added thereto and reacted at 110° C. for 21 hours. The reaction solution was returned to room temperature and diluted with γ-butyrolactone to a solid content of 20% by mass, and the solution was filtered to obtain 274.2 g of a solution of a first resin having an epoxy group and a phenolic hydroxy group. The obtained reaction product had a number average molecular weight of 3,000 and a weight average molecular weight of 7,500.

### Production Example 2

### Production of an Aqueous Alkaline Solution-Soluble Resin Having an Epoxy Group and a Phenolic Hydroxy Group (c) (Second Resin)

In a 300 mL 3-neck flask, 75.2 g of γ-butyrolactone (manufactured by Mitsubishi Chemical Corporation) as a solvent, and 37.6 g of EPICLON (trademark) N-770 (phenol novolak epoxy resin, manufactured by DIC Corporation, epoxy equivalent: 188) as a compound having at least two epoxy groups per molecule were added, and dissolved under a nitrogen gas atmosphere at 60° C. 20.1 g (0.65 equivalents with respect to one equivalent of epoxy groups) of 3,5-dihydroxybenzoic acid (manufactured by Fujifilm Wako Pure Chemical Corporation) as a hydroxybenzoic acid compound, and 0.173 g (0.660 mmol) of triphenylphosphine (manufactured by Tokyo Chemical Industry Co., Ltd.) as a reaction catalyst were added thereto and reacted at 110° C. for 21 hours. The reaction solution was returned to room temperature and diluted with γ-butyrolactone, to a solid content of 20% by mass, and the solution was filtered to obtain 197.7 g of a solution of a second resin having an epoxy group and a phenolic hydroxy group. The obtained reaction product had a number average molecular weight of 2,400 and a weight average molecular weight of 8,300.

### Production Example 3

### Production of an Aqueous Alkaline Solution-Soluble Copolymer of a Polymerizable Monomer Having an Alkali-Soluble Functional Group and an Additional Polymerizable Monomer (d) (Third Resin)

25.5 g of 4-hydroxyphenyl methacrylate (“PQMA” manufactured by Showa Denko K.K.) and 4.50 g of N-cyclohexylmaleimide (manufactured by Nippon Shokubai Co., Ltd.) were completely dissolved in 77.1 g of 1-methoxy-2-propyl acetate (manufactured by Daicel Corporation), and 3.66 g of V-601 (manufactured by Fujifilm Wako Pure Chemical Corporation) as a polymerization initiator was completely dissolved in 14.6 g of 1-methoxy-2-propyl acetate (manufactured by Daicel Corporation) as a solvent, respectively. The obtained two solutions were simultaneously added dropwise for 2 hours to 61.2 g of 1-methoxy-2-propyl acetate (Daicel Corporation) heated to 85° C. under a nitrogen atmosphere in a 300 mL 3-neck flask, and then reacted for 3 hours at 85° C. The reaction solution cooled to room temperature was added dropwise to 815 g of toluene to precipitate a copolymer. The precipitated copolymer was collected by filtration, and dried under vacuum at 90° C. for 4 hours to collect 32.4 g of an aqueous alkaline solution-soluble copolymer of a polymerizable monomer having an alkali-soluble functional group and an additional polymerizable monomer (third resin) as white powder. The obtained reaction product had a number average molecular weight of 3,100 and a weight average molecular weight of 6,600.

### (2) Raw Materials

### Binder Resin (A)

The first resin to the third resin produced in Production Examples 1 to 3 were used as the binder resin (A).

### Radiation Sensitive Compound (B)

Quinone diazide compound TPPA(4)-150DF (1,2-naphthoquinonediazido-4-sulfonic acid ester of α,α,α′-tris(4-hydroxyphenyl)-1-ethyl-4-isopropylbenzene, manufactured by Toyo Gosei Co., Ltd.), which is a photoacid generator, was used.

### Dye (C)

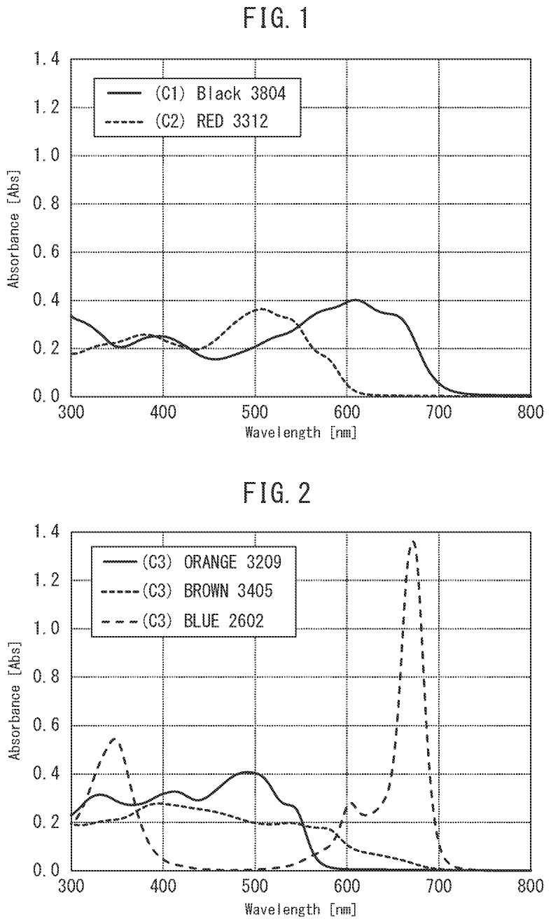

Black dyes (C1), dyes (C2) and other dyes (C3) shown in Table 1 were used as the dye. Note that, for the spectrum data a solution obtained by diluting a dye with γ-butyrolactone (GBL) so as to be 10 ppm (on a mass basis) was put into a quartz cell (cell optical path length: 1 cm) and used, and an absorption spectrum in the wavelength range of 300 to 800 nm was measured by a spectrophotometer (trade name V670, manufactured by JASCO Corporation) in increments of 1 nm at 23° C. The obtained absorbance at the wavelength of the absorption maximum was taken as Abs1, and the average value of the absorbance over the range of 560 to 600 nm wavelength was taken as the average absorbance Abs2. The absorbance curves of VALIFAST (trademark) BLACK 3804, which is a black dye (C1), and VALIFAST (trademark) RED 3312, which is a dye (C2), are shown in FIG. 1, and the absorbance curves of VALIFAST (trademark) ORANGE 3209, VALIFAST (trademark) BROWN 3405, and VALIFAST (trademark) BLUE 2602, which are other dyes (C3), are shown in FIG. 2, respectively.

TABLE 1

| | | | | | Absorbance | |
|---|---|---|---|---|---|---|
| | | | | | at 365 nm | |
| | | | | | when the | |
| | | | | | absorbance | |
| | | | | | at the | |
| | | | | Absorption | absorption | |
| | | | | maximum | maximum | |
| | | | | wavelength | wavelength | Abs2/ |
| | Trade Name | Description | Manufacturer | (nm) | is 100 | Abs1 |
| Black dye | VALIFAST ™ | C.I. Solvent black 34 | Orient Chemical Industries | 609 | 54.10 | 0.92 |
| (C1) | BLACK 3804 | | Co., Ltd. | | | |
| | VALIFAST ™ | C.I. Solvent black 27 | Orient Chemical Industries | 579 | 88.40 | 0.99 |
| | BLACK 3820 | | Co., Ltd. | | | |
| | VALIFAST ™ | C.I. Solvent black 29 | Orient Chemical Industries | 579 | 79.47 | 0.98 |
| | BLACK 3810 | | Co., Ltd. | | | |
| Dye (C2) | VALIFAST ™ | C.I. Solvent red 122 | Orient Chemical Industries | 507 | 67.37 | 0.33 |
| | RED 3312 | | Co., Ltd. | | | |
| | VALIFAST ™ | C.I. Solvent red 8 | Orient Chemical Industries | 533 | 59.36 | 0.52 |
| | RED 3311 | | Co., Ltd. | | | |
| Other | VALIFAST ™ | C.I. Solvent orange 62 | Orient Chemical Industries | 492 | 66.67 | 0.06 |
| dyes | ORANGE 3209 | | Co., Ltd. | | | |
| (C3) | VALIFAST ™ | Mixture of C.I. | Orient Chemical Industries | 395 | 83.25 | 0.53 |
| | BROWN 3405 | Solvent yellow 82 | Co., Ltd. | | | |
| | | and other dyes | | | | |
| | VALIFAST ™ | C.I. Solvent blue 44 | Orient Chemical Industries | 672 | 25.25 | 0.11 |
| | BLUE 2602 | | Co., Ltd. | | | |

### Optional Component (D)

Phloroglucinol or adipic acid was used as the dissolution accelerator. Megaface (trademark) F-559 (a fluorosurfactant, manufactured by DIC Corporation) was used as the surfactant (leveling agent).

### Solvent (F)

A mixed solvent of γ-butyrolactone (GBL) and propylene glycol monomethyl ether acetate (PGMEA) (GBL:PGMEA=40:60 (mass ratio)) was used as the solvent.

### (3) Evaluation Method

The evaluation methods used in Examples and Comparative Examples are described as follows.

### [Spectrum Data]

The average absorbance Abs3 of the photosensitive resin composition over the range of 450 to 545 nm wavelength and the average absorbance Abs4 over the range of 550 to 650 nm wavelength were measured by the following procedures. A solution obtained by diluting the photosensitive resin composition with GBL so as to be 12 ppm was put into a quartz cell (cell optical path length: 1 cm) and used, and an absorption spectrum in the wavelength range of 300 to 800 nm was measured by a spectrophotometer (trade name V670, manufactured by JASCO Corporation) in increments of 1 nm at 23° C. The average value of the obtained absorbance over the range of 450 to 545 nm wavelength and the average value of the absorbance over the range of 550 to 650 nm wavelength were respectively taken as the average absorbances Abs3 and Abs4, and Abs4/Abs3 was calculated.

### [Pattern Delamination, Pattern Residue, and Visual Residue]

The coating composition was bar-coated on a glass substrate (size: 100 mm×100 mm×1 mm) so that the dry coating thickness was about 1.5 μm, and heated on a hot plate at 120° C. for 80 seconds to dry the solvent. The coating was exposed at 100 mJ/cm² using an exposure apparatus (trade name Multilight MT-251A/B, manufactured by Ushio Inc.), in which an ultrahigh pressure mercury lamp was incorporated, through a bandpass filter for mercury lamp exposure (trade name HB0365, manufactured by Asahi Spectra Co., Ltd.) and a quartz photomask (having a line and space (L/S) pattern of 5 μm, 10 μm, 20 μm, 50 μm, 100 μm, 200 μm, or 500 μm). The exposure dose was measured using an accumulated UV meter (trade name UIT-150, light receiving unit UVD-S365, manufactured by Ushio Inc.). The exposed coating was subjected to alkali development using a spin development device (AD-1200, manufactured by Takizawa Sangyo K.K.) with an aqueous solution of 2.38% by mass of tetramethylammonium hydroxide for 60 seconds. Thereafter, the coating was cured at 250° C. for 60 minutes under a nitrogen gas atmosphere to obtain a pattern sample.

Pattern delamination was judged, based on observation of a pattern after alkali development using an optical microscope (VH-Z250, manufactured by Keyence Corporation), to be none when there was no delamination of the coating on the entire substrate, and presence when there was delamination of the coating on a part of the substrate or the entire substrate.

For the pattern residue, a pattern sample after alkali development in which the coating thickness was changed between 0.9 and 1.5 μm was observed using an optical microscope (VHX-6000, manufactured by Keyence Corporation), and the coating thickness of a sample in which there was no residue after alkali development including an edge portion of the pattern was measured using an optical film thickness measuring device (F20-NIR, manufactured by Filmetrics Japan, Inc.). The higher the number, the better the exposure sensitivity.

For the visual residue, a pattern sample after alkali development in which the coating thickness was changed between 0.9 and 1.5 μm was visually observed, and the coating thickness of a sample in which no residue was present and a glass substrate surface was visible was measured using an optical film thickness measuring device (F20-NIR, manufactured by Filmetrics Japan, Inc.). The higher the number, the better the exposure sensitivity.

### [Solubility of Unexposed Part]

The coating composition was bar-coated on a glass substrate (size: 100 mm×100 mm×1 mm) so that the dry coating thickness was about 1.5 μm, and heated on a hot plate at 120° C. for 80 seconds to dry the solvent. After the dry coating thickness was measured using an optical film thickness measuring device (F20-NIR, manufactured by Filmetrics Japan, Inc.), the coating was subjected to alkali development using a spin development device (AD-1200, manufactured by Takizawa Sangyo K.K.) with an aqueous solution of 2.38% by mass of tetramethylammonium hydroxide for 60 seconds. The coating thickness after alkali development was measured again using the optical film thickness measuring device (F20-NIR, manufactured by Filmetrics Japan, Inc.), and the coating thickness (μm) dissolved during development was calculated as the solubility of the unexposed part.

### [OD Value After Heating]

The coating composition was spin-coated on a glass substrate (size: 100 mm×100 mm×1 mm) so that the dry coating thickness was about 1.5 μm, and heated on a hot plate at 120° C. for 80 seconds to dry the solvent. Thereafter, the coating was cured at 250° C. for 60 minutes under a nitrogen gas atmosphere to obtain a coating. The OD value of the cured coating was measured with a transmission densitometer (BMT-1, manufactured by Sakata Inx Eng. Co., Ltd.), corrected using the OD value of only glass, and converted to an OD value per μm of coating thickness. The thickness of the coating was measured using an optical film thickness measuring device (F20-NIR, manufactured by Filmetrics Japan, Inc.).

### (4) Preparation and Evaluation of Photosensitive Resin Compositions

### Example 1

22.5 parts by mass (converted in terms of solid content) of the first resin solution, and 21.0 parts by mass (converted in terms of solid content) of the third resin solution were mixed and dissolved, and to the resulting solution, 24.0 parts by mass of quinone diazide compound TPPA(4)-150DF shown in Table 2, 22.4 parts by mass of VALIFAST (trademark) BLACK 3804, 5.6 parts by mass of VALIFAST (trademark) RED 3312, 3.0 parts by mass of phloroglucinol, 1.5 parts by mass of adipic acid, 0.14 parts by mass of Megaface (trademark) F-559, and the GBL/PGMEA mixed solvent were added and further mixed. After visually confirming that the components were dissolved, the mixture was filtered through a millipore filter having a pore diameter of 0.22 μm to prepare a photosensitive resin composition (coating composition) having a solid concentration of 12% by mass.

### Examples 2-7, and Comparative Examples 1-4

A photosensitive resin composition (coating composition) was prepared in the same manner as in Example 1 with the composition (parts by mass) shown in Table 2.

The prepared photosensitive resin compositions were evaluated with respect to the spectrum data, the OD value after heating, the solubility of unexposed part, the pattern delamination, the pattern residue, and the visual residue. The results are shown in Table 2. The parts by mass of the composition in Table 2 is a converted value in terms of solid content. Note that, for Comparative Example 4, since VALIFAST (trademark) BLUE 2602 was precipitated with time without being sufficiently dissolved, the evaluation other than the OD value after heating was not carried out.

TABLE 2

| | | | Ex. 1 | Ex. 2 | Ex. 3 | Ex. 4 | Ex. 5 | Ex. 6 |
|---|---|---|---|---|---|---|---|---|
| Binder resin (A) | | First resin | 22.5 | 17.0 | 17.0 | — | 19.0 | 19.0 |
| | | Second resin | — | — | — | 19.0 | — | — |
| | | Third resin | 21.0 | 26.0 | 26.0 | 24.0 | 24.0 | 24.0 |
| Radiation sensitive | | TPPA(4)-150DF | 24.0 | 24.0 | 24.0 | 26.0 | 24.0 | 24.0 |
| compound (B) | | | | | | | | |
| DYE (C) | Black dye (C1) | VALIFAST ™ BLACK 3804 | 22.4 | 22.4 | — | — | 22.4 | 18.7 |
| | | VALIFAST ™ BLACK 3820 | — | — | 22.4 | — | — | — |
| | | VALIFAST ™ BLACK 3810 | — | — | — | 20.8 | — | — |
| | Dye (C2) | VALIFAST ™ RED 3312 | 5.6 | 5.6 | 5.6 | 5.2 | — | 9.3 |
| | | VALIFAST ™ RED 3311 | — | — | — | — | 5.6 | — |
| | Other dyes (C3) | VALIFAST ™ ORANGE 3209 | — | — | — | — | — | — |
| | | VALIFAST ™ BROWN 3405 | — | — | — | — | — | — |
| | | VALIFAST ™ BLUE 2602 | — | — | — | — | — | — |

| | Optional compnent (D) | Phloroglucinol | 3.0 | 3.0 | 3.0 | 3.0 | 3.0 | 3.0 |
|---|---|---|---|---|---|---|---|---|
| | | Adipic acid | 1.5 | 2.0 | 2.0 | 2.0 | 2.0 | 2.0 |
| | | Megaface ™ F-559 | 0.14 | 0.14 | 0.14 | 0.14 | 0.14 | 0.14 |
| | Solvent (E) | GBL:PGMEA = | 733 | 733 | 733 | 733 | 733 | 733 |
| | | 40:60 (mass ratio) | | | | | | |
| | (C1)/(C) [% by mass] | | 80 | 80 | 80 | 80 | 80 | 80 |
| | (C2)/(C) [% by mass] | | 20 | 20 | 20 | 20 | 20 | 20 |
| | Amount (parts by mass) of (B) with respect to 100 | | 25 | 25 | 25 | 27 | 25 | 25 |
| | parts by mass of (A) + (B) + (C) | | | | | | | |
| Composition | Spectrum data | Average absorbance Ab3 | 0.0730 | 0.0875 | 0.0733 | 0.0787 | 0.0798 | 0.0849 |
| | | over the range of 450 to 545 nm | | | | | | |
| | | Average absorbance Ab4 over | 0.0978 | 0.1163 | 0.0767 | 0.0882 | 0.1044 | 0.0938 |
| | | the range of 550 to 650 nm | | | | | | |
| | | Abs4/Abs3 | 1.34 | 1.33 | 1.05 | 1.12 | 1.31 | 1.10 |
| Results | OD value after | | 1.00 | 1.01 | 1.01 | 1.01 | 1.00 | 1.01 |
| | heating [1 μm] | | | | | | | |
| | Solubilityof unexposed | | 0.48 | 0.49 | 0.60 | 0.50 | 0.52 | 0.55 |
| | part [μm] | | | | | | | |
| | Pattern delamination | | None | None | None | None | None | None |
| | Pattern residue [μm] | | 1.14 | 1.20 | 1.15 | 1.25 | 1.14 | 1.17 |
| | Visual residue [μm] | | 1.05 | 0.94 | 1.02 | 1.05 | 1.03 | 1.03 |

| | | | | Comp. | Comp. | Comp. | Comp. |
|---|---|---|---|---|---|---|---|
| | | | Ex. 7 | Ex. 1 | Ex. 2 | Ex. 3 | Ex. 4 |
| Binder resin (A) | | First resin | 19.0 | 22.5 | 19.0 | 19.0 | 19.0 |
| | | Second resin | — | — | — | — | — |
| | | Third resin | 24.0 | 21.0 | 24.0 | 24.0 | 24.0 |
| Radiation sensitive | | TPPA(4)-150DF | 24.0 | 24.0 | 24.0 | 24.0 | 24.0 |
| compound (B) | | | | | | | |
| DYE (C) | Black dye (C1) | VALIFAST ™ BLACK 3804 | 24.9 | 28.0 | 22.4 | 22.4 | 22.4 |
| | | VALIFAST ™ BLACK 3820 | — | — | — | — | — |
| | | VALIFAST ™ BLACK 3810 | — | — | — | — | — |
| | Dye (C2) | VALIFAST ™ RED 3312 | 3.1 | — | — | — | — |
| | | VALIFAST ™ RED 3311 | — | — | — | — | — |
| | Other dyes (C3) | VALIFAST ™ ORANGE 3209 | — | — | — | 5.6 | — |
| | | VALIFAST ™ BROWN 3405 | — | — | 5.6 | — | — |
| | | VALIFAST ™ BLUE 2602 | — | — | — | — | 5.6 |

| | Optional compnent (D) | Phloroglucinol | 3.0 | 3.0 | 3.0 | 3.0 | 3.0 |
|---|---|---|---|---|---|---|---|
| | | Adipic acid | 2.0 | 1.5 | 2.0 | 2.0 | 2.0 |
| | | Megaface ™ F-559 | 0.14 | 0.14 | 0.14 | 0.14 | 0.14 |
| | Solvent (E) | GBL:PGMEA = | 733 | 733 | 733 | 733 | 733 |
| | | 40:60 (mass ratio) | | | | | |
| | (C1)/(C) [% by mass] | | 89 | 100 | 80 | 80 | 80 |
| | (C2)/(C) [% by mass] | | 11 | 0 | 0 | 0 | 0 |
| | Amount (parts by mass) of (B) with respect to 100 | | 25 | 25 | 25 | 25 | 25 |
| | parts by mass of (A) + (B) + (C) | | | | | | |
| Composition | Spectrum data | Average absorbance Ab3 | 0.0742 | 0.0694 | 0.0838 | 0.0997 | 0.0707 |
| | | over the range of 450 to 545 nm | | | | | |
| | | Average absorbance Ab4 over | 0.1113 | 0.1207 | 0.1130 | 0.1232 | 0.1461 |
| | | the range of 550 to 650 nm | | | | | |
| | | Abs4/Abs3 | 1.50 | 1.74 | 1.35 | 1.24 | 2.07 |
| Results | OD value after | | 1.01 | 1.00 | 0.94 | 0.94 | 0.90 |
| | heating [1 μm] | | | | | | |
| | Solubility of | | 0.50 | 0.46 | 0.55 | 0.55 | Not evaluated |
| | unexposed part [μm] | | | | | | |
| | Pattern delamination | | None | None | None | None | Not evaluated |
| | Pattern residue [μm] | | 1.17 | 1.12 | 1.12 | 1.08 | Not evaluated |
| | Visual residue [μm] | | 1.03 | 0.93 | 0.99 | 0.99 | Not evaluated |

### INDUSTRIAL APPLICABILITY

The photosensitive resin composition according to the present invention can be suitably used in radiation lithography for forming barrier ribs or an insulating film of an organic EL element. Organic EL elements provided with barrier ribs or an insulating film formed by using the photosensitive resin composition according to the present invention is suitable for use as an electronic component in a display device exhibiting high contrast.

1. A photosensitive resin composition comprising
a binder resin (A);
a radiation sensitive compound (B); and
a dye (C),
wherein the dye (C) comprises a black dye (C1) and a dye (C2) other than (C1), wherein the dye (C2) has the absorption maximum at a wavelength from 480 to 550 nm in the wavelength range of 300 to 800 nm, and wherein Abs2/Abs1 is 0.1 to 1.0 when the absorbance at the wavelength of the absorption maximum of the dye (C2) is taken as Abs1 and the average absorbance over the range of 560 to 600 nm wavelength is taken as Abs2.

2. The photosensitive resin composition according to claim 1, wherein Abs4/Abs3 is 0.8 to 1.6 when the average absorbance over the range of 450 to 545 nm wavelength is taken as Abs3 and the average absorbance over the range of 550 to 650 nm wavelength is taken as Abs4 in the absorbance curve of the photosensitive resin composition.

3. The photosensitive resin composition according to claim 1, wherein the absorbance at 365 nm wavelength of the dye (C2) is 0 to 80 when the absorbance at the wavelength of the absorption maximum of the dye (C2) in the wavelength range of 300 to 800 nm is 100.

4. The photosensitive resin composition according to claim 1, wherein the photosensitive resin composition comprises 50 to 95% by mass of the black dye (C1) with respect to the total mass of the dye (C).

5. The photosensitive resin composition according to claim 1, wherein the dye (C2) is a red dye.

6. The photosensitive resin composition according to claim 1, wherein the photosensitive resin composition comprises 5 to 35% by mass of the dye (C2) with respect to the total mass of the dye (C).

7. The photosensitive resin composition according to claim 1, wherein the black dye (C1) is defined by the color index as solvent black 7 to 47.

8. The photosensitive resin composition according to claim 1, wherein the radiation sensitive compound (B) is at least one photoacid generator selected from the group consisting of quinone diazide compounds, sulfonium salts, phosphonium salts, diazonium salts, and iodonium salts.

9. The photosensitive resin composition according to claim 8, comprising 5 parts by mass to 50 parts by mass of the photoacid generator with respect to 100 parts by mass of the total of the binder resin (A), the radiation sensitive compound (B), and the dye (C).

10. The photosensitive resin composition according to claim 1, wherein the binder resin (A) has an alkali-soluble functional group.

11. The photosensitive resin composition according to claim 1, comprising 15 parts by mass to 50 parts by mass of the dye (C) with respect to 100 parts by mass of the total of the binder resin (A), the radiation sensitive compound (B), and the dye (C).

12. The photosensitive resin composition according to claim 1, wherein the binder resin (A) is at least one selected from the group consisting of:
(a) a polyalkenylphenolic resin having a structural unit represented by formula (1) 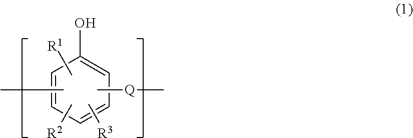
wherein in formula (1), R¹, R² and R³ each independently represent a hydrogen atom; an alkyl group having 1 to 5 carbon atoms; an alkenyl group represented by formula (2) 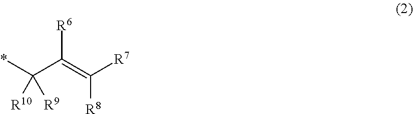
wherein in formula (2), R⁶, R⁷, R⁸, R⁹ and R¹⁰ each independently represent a hydrogen atom, an alkyl group having 1 to 5 carbon atoms, a cycloalkyl group having 5 to 10 carbon atoms, or an aryl group having 6 to 12 carbon atoms, * in formula (2) represents a bonding site with a carbon atom constituting the aromatic ring; an alkoxy group having 1 to 2 carbon atoms; or a hydroxy group, and at least one of R¹, R² and R³ is the alkenyl group represented by formula (2), Q is an alkylene group represented by the formula —CR⁴R⁵—, a cycloalkylene group having 5 to 10 carbon atoms, a divalent organic group having an aromatic ring, a divalent organic group having an alicyclic fused ring, or a divalent group consisting of a combination thereof, R⁴ and R⁵ each independently represent a hydrogen atom, an alkyl group having 1 to 5 carbon atoms, an alkenyl group having 2 to 6 carbon atoms, a cycloalkyl group having 5 to 10 carbon atoms, or an aryl group having 6 to 12 carbon atoms;
(b) a hydroxypolystyrene resin derivative having a structural unit represented by formula (3) 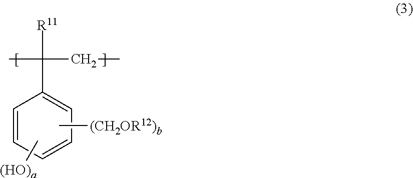
wherein in formula (3), R¹¹ represents a hydrogen atom or an alkyl group having 1 to 5 carbon atoms, a is an integer from 1 to 4, b is an integer from 1 to 4, a+b is in the range of 2 to 5, and R¹² is at least one selected from the group consisting of a hydrogen atom, a methyl group, an ethyl group, and a propyl group;
(c) an aqueous alkaline solution-soluble resin having an epoxy group and a phenolic hydroxy group; and
(d) an aqueous alkaline solution-soluble copolymer of a polymerizable monomer having an alkali-soluble functional group and an additional polymerizable monomer.

13. The photosensitive resin composition according to claim 1, wherein the binder resin (A) is at least one selected from the group consisting of:
(c) an aqueous alkaline solution-soluble resin having an epoxy group and a phenolic hydroxy group; and
(d) an aqueous alkaline solution-soluble copolymer of a polymerizable monomer having an alkali-soluble functional group and an additional polymerizable monomer.

14. An organic EL element barrier rib comprising a cured product of the photosensitive resin composition according to claim 1.

15. An organic EL element insulating film comprising a cured product of the photosensitive resin composition according to claim 1.

16. An organic EL element comprising a cured product of the photosensitive resin composition according to claim 1.
